(19) United States
(12) Patent Application Publication
(10) Pub. No.: US 2024/0018306 A1
(43) Pub. Date: Jan. 18, 2024

(54) RESIN COMPOSITION, METHOD FOR PRODUCING SEMICONDUCTOR DEVICE, CURED PRODUCT, SEMICONDUCTOR DEVICE, AND METHOD FOR SYNTHESIZING POLYIMIDE PRECURSOR

(71) Applicants: RESONAC CORPORATION, Bunkyo-ku, Tokyo (JP); HD MICROSYSTEMS, LTD., Manato-ku, Tokyo (JP)

(72) Inventors: Satoshi YONEDA, Chiyoda-ku, Tokyo (JP); Yutaka NAMATAME, Bunkyo-ku, Tokyo (JP); Tomoaki SHIBATA, Chiyoda-ku, Tokyo (JP); Kaori KOBAYASHI, Bunkyo-ku, Tokyo (JP); Hitoshi ONOZEKI, Chiyoda-ku, Tokyo (JP); Naoya SUZUKI, Chiyoda-ku, Tokyo (JP); Toshihisa NONAKA, Chiyoda-ku, Tokyo (JP)

(21) Appl. No.: 18/029,102

(22) PCT Filed: Sep. 28, 2021
(86) PCT No.: PCT/JP2021/035672

§ 371 Date: Mar. 29, 2023

(30) Foreign Application Priority Data
Sep. 30, 2020 (WO) PCT/JP2020/037322

(51) Int. Cl. C08G 73/10

(52) U.S. Cl. CPC C08G 73/1007; C08G 73/1032

(57) ABSTRACT

A resin composition that contains (A) at least one of a polyimide precursor, which is at least one resin selected from the group consisting of a polyamide acid, a polyamide acid ester, a polyamide acid salt, and a polyamide acid amide, or a polyimide resin, and (B) a solvent, and that is used for preparing an insulating film for at least one of a first organic insulating film or a second organic insulating film in a method for producing a semiconductor device including processes (1) to (5).

### TECHNICAL FIELD

The present disclosure relates to a resin composition, a method for producing a semiconductor device, a cured product, a semiconductor device, and a method for synthesizing a polyimide precursor.

### BACKGROUND ART

In recent years, three-dimensional mounting of semiconductor chips has been studied to improve the integration of LSI (Large Scale Integrated Circuit). Non-Patent Document 1 discloses an example of three-dimensional mounting of semiconductor chips.

In the case of three-dimensional mounting of semiconductor chips by C2W (Chip-to-Wafer) bonding, the use of hybrid bonding technology used for W2 W (Wafer-to-Wafer) bonding is studied in order to perform micro bonding of wiring between devices.

In C2W hybrid bonding, there is a risk of misalignment caused by thermal expansion of a base material, a chip, or the like due to heating during bonding. To address such a problem, Patent Document 1 discloses an example of a technique that can lower the bonding temperature by using a cyclic olefin resin.

### CITATION LIST

### Patent Document

Patent Document 1 Japanese Patent Application Laid-Open (JP-A) No. 2019-Non-Patent Document
Non-Patent Document 1 F. C. Chen et al., “System on Integrated Chips (SoIC™) for 3D Heterogeneous Integration”, 2019 IEEE 69th Electronic Components and Technology Conference (ECTC), p. 594-599(2019)

### SUMMARY OF INVENTION

### Technical Problem

When three-dimensional mounting of a semiconductor chip is performed by C2W bonding, unlike W2 W bonding, a foreign matter (cutting chip) may be generated in a process of individualization into semiconductor chips, and this foreign matter may adhere to the bonding interface (surface of an insulating film of hybrid bonding) of semiconductor chips or the like. Use of an inorganic material such as silicon dioxide (Sift) as an insulating film has been considered, but because inorganic materials are hard, a foreign matter that adheres thereto can create a large void in the insulating film, for example, a void nearly 1,000 times wider than the height of the foreign matter, at a bonding interface. Therefore, even when a hybrid bonding technique used for W2 W bonding is simply applied to C2W bonding, generation of such a void may cause a bonding defect, resulting in a lower yield rate in semiconductor device manufacturing. On the other hand, when a clean room with high cleanliness and equipment are used to prevent such bonding defects, a large amount of money is required due to capital investment in such a clean room and the like.

When an organic material such as a cyclic olefin resin is used as an insulating film material, the organic material does not have sufficient heat resistance, and exposure of the insulating film to high temperatures during C2W bonding may alter the organic material, causing a bonding defect at an interface between a substrate and the insulating film or the like.

The disclosure is made in view of the above, and an object of the disclosure is to provide a resin composition capable of producing a semiconductor device provided with an insulating film having excellent heat resistance and reducing generation of a void at a bonding interface, a method for producing a semiconductor device using the above-described resin composition, a cured product made by curing the above-described resin composition, and a semiconductor device provided with an insulating film having excellent heat resistance and reducing generation of a void at a bonding interface.

Another object of the disclosure is to provide a method for synthesizing a polyimide precursor that is capable of synthesizing a polyimide precursor for use in preparing the above-described resin composition.

### Solution to Problem

Specific means to solve the above-described problems are as follows.

<1> A resin composition that contains (A) at least one of a polyimide precursor, which is at least one resin selected from the group consisting of a polyamide acid, a polyamide acid ester, a polyamide acid salt, and a polyamide acid amide, or a polyimide resin, and (B) a solvent, and

that is used for preparing an organic insulating film for at least one of a first organic insulating film or a second organic insulating film in a method for producing a semiconductor device comprising the following processes (1) to (5).

Process (1) A first semiconductor substrate comprising a first substrate body and the first organic insulating film and a first electrode provided on one side of the first substrate body are prepared.

Process (2) A second semiconductor substrate comprising a second substrate body and the second organic insulating film and a plurality of second electrodes provided on one side of the second substrate body are prepared.

Process (3) The second semiconductor substrate is broken into pieces to obtain a plurality of semiconductor chips each having an organic insulating film portion corresponding to a portion of the second organic insulating film and at least one of the second electrodes,

Process (4) The first organic insulating film of the first semiconductor substrate and the organic insulating film portion of the semiconductor chip are attached to each other.

Process (5) The first electrode of the first semiconductor substrate and the second electrode of the semiconductor chip are bonded together.

<2> A resin composition that comprises (A) at least one of a polyimide precursor, which is at least one resin selected from the group consisting of a polyamide acid, a polyamide acid ester, a polyamide acid salt, and a polyamide acid amide, or a polyimide resin and (B) a solvent, and

that is used for preparing a cured product to be polished by a chemical mechanical polishing method together with an electrode.

<3> The resin composition according to <1> or <2>, wherein (A) the polyimide precursor comprises a compound containing a structural unit represented by the following Formula (1).

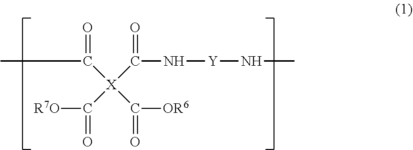

In Formula (1), X represents a tetravalent organic group, Y represents a divalent organic group, and each of R⁶ and R⁷ independently represents a hydrogen atom or a monovalent organic group.

<4> The resin composition according to <3>, wherein the tetravalent organic group represented by X in Formula (1) is a group represented by the following Formula (E).

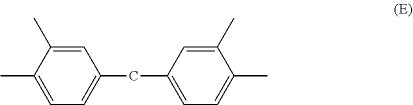

In Formula (E), C represents a single bond, an alkylene group, an alkylene halide group, a carbonyl group, a sulfonyl group, an ether bond (—O—), a sulfide bond (—S—), a phenylene group, an ester bond (—O—C(═O)—), a silylene bond (—Si(R^{A})₂— in which each of the two R^{A}s independently represents a hydrogen atom, an alkyl group, or a phenyl group), a siloxane bond (—O—(Si(R^{B})₂—O—)ₙ in which each of the two les independently represents a hydrogen atom, an alkyl group or a phenyl group, and n is an integer of 1 or 2 or more), or a divalent group combining at least two of these.

<5> The resin composition according to <3> or <4>, wherein the divalent organic group represented by Y in Formula (1) is a group represented by the following Formula (H).

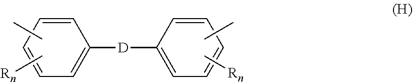

In Formula (H), R independently represents an alkyl group, an alkoxy group, an alkyl halide group, a phenyl group, or a halogen atom; n independently represents an integer from 0 to 4, and D represents a single bond, an alkylene group, an alkylene halide group, a carbonyl group, a sulfonyl group, an ether bond (—O—), a sulfide bond (—S—), a phenylene group, an ester bond (—O—C(═O)—), a silylene bond (—Si(R^{A})₂— in which each of the two R^{A}s independently represents a hydrogen atom, an alkyl group, or a phenyl group), a siloxane bond (—O—(Si(R^{B})₂—O—)ₙ in which each of the two R^{B}s independently represents a hydrogen atom, an alkyl group or a phenyl group, and n is an integer of 1 or 2 or more), or a divalent group combining at least two of these.

<6> The resin composition according to any one of <3> to <5>, wherein the monovalent organic group in each of R⁶ and R⁷ in Formula (1) is a group represented by the following Formula (2), an ethyl group, an isobutyl group, or a t-butyl group.

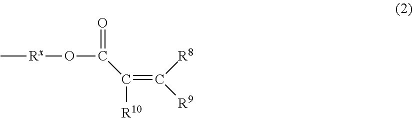

In Formula (2), each of R⁸ to R¹⁰ independently represents a hydrogen atom or an aliphatic hydrocarbon group having from 1 to 3 carbon atoms, and R^{x} represents a divalent linking group.

<7> The resin composition according to any one of <1> to <6>, wherein a content of (B) the solvent is from 1 to 10,000 parts by mass with respect to 100 parts by mass of a total of (A) the polyimide precursor and the polyimide resin.
<8> The resin composition according to any one of <1> to <7>, wherein (B) the solvent contains at least one of the group consisting of compounds represented by the following Formula (3) to Formula (7).

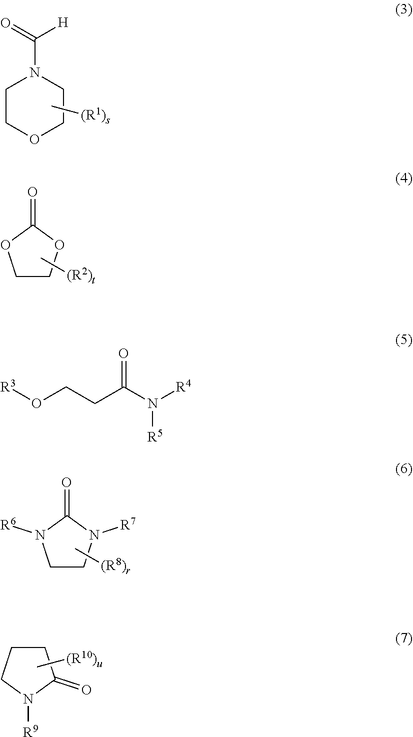

In Formulas (3) to (7), each of R¹, R², R⁸, and R¹⁰ is independently an alkyl group having from 1 to 4 carbon atoms; each of R³ to R⁷ and R⁹ is independently a hydrogen atom or an alkyl group having from 1 to 4 carbon atoms; s is an integer from 0 to 8; t is an integer from 0 to 4; r is an integer from 0 to 4, and u is an integer from 0 to 3.

<9> The resin composition according to any one of <1> to <8>, wherein a 5% thermal weight loss temperature of a cured product obtained by curing the resin composition is 200° C. or higher.
<10> The resin composition according to any one of <1> to <9>, wherein a glass transition temperature of a cured product obtained by curing the resin composition is from 100° C. to 400° C.
<11> The resin composition according to any one of <1> to <10>, wherein, for a cured product obtained by curing the resin composition, a ratio of a storage modulus G2 at a temperature 100° C. higher than a glass transition temperature (Tg) of the cured product as determined by dynamic viscoelasticity measurement to a storage modulus G1 at a temperature 100° C. lower than a glass transition temperature (Tg) of the cured product as determined by dynamic viscoelasticity measurement, G2/G1, is from 0.001 to 0.02.
<12> The resin composition according to any one of <1> to <11>, further comprising (C) a photoinitiator and (D) a polymerizable monomer.
<13> The resin composition of any one of <1> to <12>, which is a negative-type photosensitive resin composition or a positive-type photosensitive resin composition, for use in providing a plurality of through holes for arranging a plurality of terminal electrodes on an organic insulating film provided on one surface of a substrate body by a photolithographic process.
<14> The resin composition according to any one of <1> to <13>, wherein a tensile modulus at 25° C. of a cured product is 7.0 GPa or less.
<15> The resin composition of any one of <1> to <14>, wherein a thermal expansion coefficient of a cured product obtained by curing is 150 ppm/K or less.
<16> A method for producing a semiconductor device, wherein the resin composition according to any one of <1> to <15> is used for producing at least one organic insulating film of a first organic insulating film or a second organic insulating film, and wherein a semiconductor device is produced by performing the following processes (1) to (5).

Process (1) A first substrate body and a first semiconductor substrate including the first organic insulating film or a first electrode provided on one side of the first substrate body are prepared.

Process (2) A second substrate body and a second semiconductor substrate including the second organic insulating film and a plurality of second electrodes provided on one side of the second substrate body are prepared.

Process (3) The second semiconductor substrate is broken into pieces to obtain a plurality of semiconductor chips each having an organic insulating film portion corresponding to a portion of the second organic insulating film and at least one of the second electrodes.

Process (4) The first organic insulating film of the first semiconductor substrate and the organic insulating film portion of the semiconductor chip are attached to each other.

Process (5) The first electrode of the first semiconductor substrate and the second electrode of the semiconductor chip are bonded together.

<17> The method for producing a semiconductor device according to <16>, wherein the first organic insulating film and the organic insulating film portion are bonded together at a temperature at which a temperature difference between the semiconductor chip and the first semiconductor substrate is within 10° C. in the process (4).
<18> The method for producing a semiconductor device according to <16> or <17>, wherein in the produced semiconductor device, a thickness of an organic insulating film formed by bonding the first organic insulating film and the organic insulating film portion is 0.1 μm or more.
<19> The method for producing a semiconductor device according to any one of <16> to <18>, wherein at least one of that the process (1) comprises polishing the one surface side of the first semiconductor substrate or that the process (2) comprises polishing the one surface side of the second semiconductor substrate is satisfied, and at least one of that a polishing rate of the first organic insulating film is from 0.1 to 5 times a polishing rate of the first electrode or that a polishing rate of the second organic insulating film is from 0.1 to 5 times a polishing rate of the second electrode is satisfied.
<20> The method for producing a semiconductor device according to any one of <16> to <19>, wherein a thickness of the second insulating film is greater than a thickness of the first insulating film.
<21> The method for producing a semiconductor device according to any one of <16> to <19>, wherein a thickness of the second insulating film is smaller than a thickness of the first insulating film.
<22> A cured product obtained by curing the resin composition according to any one of <1> to <15>.
<23> A semiconductor device comprising:

a first semiconductor substrate including a first substrate body, and a first organic insulating film and a first electrode provided on one side of the first substrate body; and

a semiconductor chip including a semiconductor chip substrate body, and an organic insulating film portion and a second electrode provided on one side of the semiconductor chip substrate body, wherein

the first organic insulating film of the first semiconductor substrate and the organic insulating film portion of the semiconductor chip are bonded, and the first electrode of the first semiconductor substrate and the second electrode of the semiconductor chip are bonded, and

at least one of the first organic insulating film or the organic insulating film portion is an organic insulating film obtained by curing the resin composition according to any one of <1> to <15>.

<24> A method for synthesizing a polyimide precursor, the method comprising:

a process of reacting tetracarboxylic dianhydride with a diamine compound represented by H₂N—Y—NH₂ (wherein Y is a divalent organic group) in 3-methoxy-N,N-dimethylpropanamide to obtain a polyamide acid solution; and

a process of allowing a dehydration condensation agent and a compound represented by R—OH (wherein R is a monovalent organic group) to act on the polyamide acid solution.

<25> The method for synthesizing a polyimide precursor according to <24>, wherein the dehydration condensation agent comprises at least one selected from the group consisting of trifluoroacetic anhydride, N,N′-dicyclohexylcarbodiimide (DCC), and 1,3-diisopropylcarbodiimide (DIC).

### Advantageous Effects of Invention

The disclosure can provide a resin composition capable of producing a semiconductor device provided with an insulating film having excellent heat resistance and reducing generation of a void at a bonding interface, a method for producing a semiconductor device using the above-described resin composition, a cured product made by curing the above-described resin composition, and a semiconductor device provided with an insulating film having excellent heat resistance and reducing generation of a void at a bonding interface.

The disclosure can also provide a method for synthesizing a polyimide precursor that is capable of synthesizing a polyimide precursor for use in preparing the above-described resin composition.

### BRIEF DESCRIPTION OF DRAWINGS

FIG. 1 is a schematic sectional view of an example of a semiconductor device produced by a method of producing a semiconductor device according to an embodiment of the invention.

FIG. 2 is a view illustrating a method for producing the semiconductor device illustrated in FIG. 1, in sequence.

FIG. 3 is a view illustrating in more detail a bonding method in the method for producing a semiconductor device illustrated in FIG. 2.

FIG. 4 illustrates, in sequence, processes after the process illustrated in FIG. 2 in the method for manufacturing the semiconductor device illustrated in FIG. 1.

FIG. 5 is a view illustrating an example of a method for producing semiconductor devices according to one embodiment of the invention applied to a Chip-to-Wafer (C2W).

### DESCRIPTION OF EMBODIMENTS

Hereinafter, embodiments for carrying out the disclosure will be described in detail. The disclosure, however, is not limited to the following embodiments. In the following embodiments, components (including elemental steps or the like) thereof are not necessary, unless specifically indicated otherwise. The same applies to numerical values and ranges thereof, which do not limit the disclosure.

In the disclosure, the term “A or B” may include either A or B, or both.

In the disclosure, the term “process” includes not only a process that is independent of other processes, but also a process that is not clearly distinguishable from other processes, but whose purpose is achieved.

The numerical range indicated in the disclosure using “from A to B” includes A and B as the lower limit and the upper limit, respectively.

In a numerical range described in steps herein, an upper limit value or a lower limit value described in one numerical range may be replaced by upper limit values or lower limit values in other stepwise described numerical ranges. In a numerical range described herein, an upper limit value or a lower limit value of the numerical range may be replaced by values indicated in Examples.

In the disclosure, each component may contain a plurality of kinds of corresponding substances. When a composition contains a plurality of kinds of substances corresponding to each component, the content rate or content amount of each component means the total content rate or content amount of such plurality of substances present in the composition, unless otherwise specified.

The term “layer” or “film” herein encompasses, when observing an area in which the layer or film exists, cases in which the layer or film is formed over the entire area as well as cases in which the layer or film is formed only in a portion of the area.

In the disclosure, the thickness of a layer or film is a value given as the arithmetic mean of measured thicknesses at five points of a target layer or film.

The thickness of a layer or film can be measured using a micrometer or similar instrument. In the disclosure, when the thickness of a layer or film can be measured directly, a micrometer is used to measure the thickness. On the other hand, when the thickness of one layer or the total thickness of a plurality of layers is to be measured, the thickness may be measured by observing a section of an object to be measured using an electron microscope.

In the disclosure, the term “(meth)acrylic group” means “acrylic group” and “methacrylic group”.

When a functional group has a substituent in the disclosure, the number of carbon atoms in the functional group means the total number of carbon atoms including the number of carbon atoms in the substituent.

When embodiments are described in the disclosure with reference to the drawings, the configuration of the embodiments is not limited to the configuration illustrated in the drawings. The sizes of the components in each drawing are conceptual, and the relative relationship of sizes between components is not limited thereto.

<Resin Compositions >

The resin composition of the disclosure is a resin composition that contains (A) at least one of a polyimide precursor, which is at least one resin selected from the group consisting of a polyamide acid, a polyamide acid ester, a polyamide acid salt, and a polyamide acid amide, or a polyimide resin, and (B) a solvent, and that is used for preparing an insulating film for at least one of a first organic insulating film or a second organic insulating film in a method for producing a semiconductor device including the following processes (1) to (5).

Process (1) A first semiconductor substrate including a first substrate body and the first organic insulating film and a first electrode provided on one side of the first substrate body are prepared.

Process (2) A second semiconductor substrate including a second substrate body and the second organic insulating film and a plurality of second electrodes provided on one side of the second substrate body are prepared.

Process (3) The second semiconductor substrate is broken into pieces to obtain a plurality of semiconductor chips each having an organic insulating film portion corresponding to a portion of the second organic insulating film and at least one of the second electrodes,

Process (4) The first organic insulating film of the first semiconductor substrate and the organic insulating film portion of the semiconductor chip are attached to each other.

Process (5) The first electrode of the first semiconductor substrate and the second electrode of the semiconductor chip are bonded together.

Specific examples of each of the above-described processes (1) to (5) are described in a section on the method for producing a semiconductor device described below.

An insulating film, which is a cured product obtained by curing a resin composition containing (A) at least one of a polyimide precursor or a polyimide resin, has a lower elastic modulus and is softer than a molded product composed of an inorganic material. Therefore, when the first organic insulating film and the second organic insulating film, at least one of which is the insulating film, are attached together, even when a foreign matter or the like exists on the surface of the first organic insulating film or the second organic insulating film, an insulating film at a bonding interface can be easily deformed and the foreign matter can be contained in the insulating film without creating a large void in the insulating film. Furthermore, a cured product obtained by curing a resin composition containing at least one of a polyimide precursor or a polyimide resin has higher heat resistance than a cured product obtained by curing a resin composition containing an acrylic resin, an epoxy resin, or the like, and therefore tends to reduce occurrence of a bonding defect at an interface between a substrate and an insulating film, or the like, due to resin deterioration in a semiconductor device production process. From the above points, the resin composition of the disclosure can achieve excellent reliability and high yield in a semiconductor device production process.

A modification of the resin composition of the disclosure may be a resin composition that includes (A) at least one of a polyimide precursor, which is at least one resin selected from the group consisting of a polyamide acid, a polyamide acid ester, a polyamide acid salt, and a polyamide acid amide, or a polyimide resin and (B) a solvent, and that is used for preparing a cured product to be polished by a chemical mechanical polishing (CMP) method together with an electrode.

With the resin composition of the modification, it is easy to adjust the thickness of an electrode and the thickness of an insulating film suitably when polishing the electrode, which is made of a metal such as copper, and the insulating film, which is a cured product obtained by curing the resin composition, by the CMP method. For example, it is easy to adjust the surface of an insulating film to be slightly lower than the surface of an electrode, and preferably, the difference in height between the surface of an insulating film and the surface of an electrode is easy to adjust to from 1 nm to 300 nm. Therefore, the resin composition of the modification has excellent CMP adaptability.

From the viewpoint of heat resistance of a cured product, the 5% thermal weight loss temperature of a cured product obtained by curing the resin composition of the disclosure is preferably 200° C. or higher, and more preferably 250° C. or higher. The upper limit of the 5% thermal weight loss temperature of a cured product is not particularly limited, and may be, for example, 450° C. or lower.

The 5% thermal weight loss temperature of a cured product is measured as follows. First, a resin composition is heated under a nitrogen atmosphere at a predetermined curing temperature (for example, from 150° C. to 375° C.) at which a curing reaction is possible for at least 1 hour to obtain a cured product. The obtained 10 mg of cured product is placed in a thermogravimetric analyzer (for example, TGA-50 manufactured by Shimadzu Corporation), and the temperature is increased from 25° C. to 500° C. under a nitrogen atmosphere at a rate of and the temperature at which the weight is reduced by 5% from before the temperature increase is defined as the 5% thermal weight loss temperature.

From the viewpoint of bonding at low temperatures, the glass transition temperature of a cured product obtained by curing the resin composition of the disclosure is preferably from 100° C. to 400° C., and more preferably from 150° C. to 350° C.

The glass transition temperature of a cured product is measured as follows. First, a resin composition is heated under a nitrogen atmosphere for 2 hours at a predetermined curing temperature (for example, from 150° C. to 375° C.) at which a curing reaction is possible to obtain a cured product. The obtained cured product is cut to prepare a 5 mm×50 mm×3 mm rectangle, and the dynamic viscoelasticity is measured in a temperature range of from 50° C. to 350° C. using a tensile jig with a frequency of 1 Hz and a temperature increase rate of 5° C./minute on a dynamic viscoelasticity measurement apparatus (for example, RSA-G2 manufactured by TA Instruments). The glass transition temperature (Tg) is defined as the temperature of the peak top portion in tans, which is obtained from the ratio of the storage modulus to the loss modulus obtained by the above-described method.

For a cured product obtained by curing the resin composition of the disclosure, the ratio of the storage modulus G2 at a temperature 100° C. higher than the glass transition temperature (Tg) of the cured product as determined by dynamic viscoelasticity measurement to the storage modulus G1 at a temperature 100° C. lower than the glass transition temperature (Tg) of the cured product as determined by dynamic viscoelasticity measurement, G2/G1, is preferably from 0.001 to 0.02.

In the present disclosure, the storage modulus can be measured by the method described in the description of the method for measuring the glass transition temperature.

The resin composition of the disclosure may be a negative-type photosensitive resin composition or a positive-type photosensitive resin composition. A negative-type photosensitive resin composition or a positive-type photosensitive resin composition may be used for at least one of providing a plurality of through holes for arranging a plurality of terminal electrodes in the first organic insulating film provided on one surface of the first substrate body in the above-described process (1), or providing a plurality of through holes for arranging a plurality of terminal electrodes in the second organic insulating film provided on one surface of the second substrate body in the above-described process (2).

From the viewpoint of reducing bonding defects more suitably by containing a foreign matter in an insulating film without creating a large void when the foreign matter adheres to a bonding interface, the tensile modulus at 25° C. of a cured product obtained by curing the resin composition of the disclosure is preferably 7.0 GPa or less, more preferably 5.0 GPa or less, still more preferably 3.0 GPa or less, particularly preferably 2.0 GPa or less, and further preferably 1.5 GPa or less. A cured product obtained by curing the resin composition of the disclosure has a lower tensile modulus than an inorganic material such as silicon dioxide (SiO₂).

In the disclosure, the tensile modulus is a value measured at 25° C. in accordance with JIS K 7161 (1994).

Regarding a cured product obtained by curing the resin composition of the disclosure, the storage modulus at 300° C. may be from 0.5 GPa to 0.001 GPa, or from 0.1 GPa to 0.01 GPa.

The thermal expansion coefficient of a cured product obtained by curing the resin composition of the disclosure is preferably 150 ppm/K or less, more preferably 100 ppm/K or less, and still more preferably 70 ppm/K or less. As a result, the thermal expansion coefficient of an insulating film, which is a cured product, and the thermal expansion coefficient of an electrode are equal or close to each other, and therefore, even when heat is generated during use of a semiconductor device, damage to the semiconductor device due to the difference in thermal expansion coefficient between the insulating layer and the electrode can be reduced. The thermal expansion coefficient is the ratio of the expansion of the length of a cured product due to an increase in temperature, expressed per temperature, and can be calculated by measuring the change in the length of the cured product at from 100° C. to 150° C. using a thermomechanical analyzer or the like.

The following is a description of components that are included and that can be included in the resin composition of the disclosure.

((A) Polyimide Precursor and Polyimide Resin)

The resin composition of the disclosure includes (A) at least one of a polyimide precursor, which is at least one resin selected from the group consisting of a polyamide acid, a polyamide acid ester, a polyamide acid salt, and a polyamide acid amide, or a polyimide resin (hereinafter, also referred to as “(A) component”). (A) the component is preferably at least one of a polyimide precursor or a polyimide resin from which a cured product exhibiting a high property (for example, heat resistance) can be produced, and it is more preferable to include a polyimide precursor containing a polymerizable unsaturated bond as the polyimide precursor. (A) the component contained in a resin composition is preferably a component that does not cause a defect in a polishing process, a bonding process, or the like.

In the disclosure, a polyimide precursor means a compound corresponding to any of polyamide acid, a compound in which a hydrogen atom of at least some carboxy groups in polyamide acid is replaced by a monovalent organic group, or a polyamide acid salt which is a compound in which at least some carboxy groups in polyamide acid form a salt structure with a basic compound at pH 7 or higher.

Examples of the compound in which at least some hydrogen atoms of carboxy groups in polyamide acid are replaced with monovalent organic groups include a polyamide acid ester and a polyamide acid amide.

A polyamide acid ester, a polyamide acid amide, or the like preferably contains a polymerizable unsaturated bond.

When (A) a component contains a polyimide precursor, (A) the component preferably contains a compound containing a structural unit represented by the following Formula (1). As a result, a semiconductor device including an insulating film exhibiting high reliability tends to be obtained.

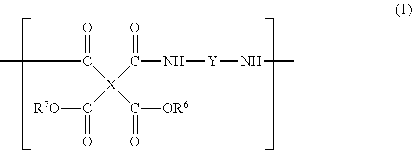

In Formula (1), X represents a tetravalent organic group and Y represents a divalent organic group. Each of R⁶ and R⁷ independently represents a hydrogen atom or a monovalent organic group.

A polyimide precursor may contain a plurality of structural units represented by the above-described Formula (1), and X, Y, R⁶, and R⁷ in the plurality of structural units may be the same or different from each other.

The combination of R⁶ and R⁷ is not particularly limited as long as R⁶ and R⁷ are independently a hydrogen atom or a monovalent organic group, respectively. For example, each of R⁶ and R⁷ may be a hydrogen atom, one may be a hydrogen atom and the other may be a monovalent organic group as described below, or both may be the same or different monovalent organic groups. When a polyimide precursor contains a plurality of structural units represented by the above-described Formula (1) as described above, combinations of R⁶ and R⁷ of the structural units may be the same or different from each other.

In Formula (1), the number of carbon atoms of a tetravalent organic group represented by X is preferably from 4 to 25, more preferably from 5 to 13, and still more preferably from 6 to 12.

A tetravalent organic group represented by X may contain an aromatic ring. Examples of the aromatic ring include an aromatic hydrocarbon group (for example, the number of carbon atoms constituting the aromatic ring is from 6 to 20) and an aromatic heterocyclic group (for example, the number of atoms constituting the heterocyclic ring is from 5 to 20). The tetravalent organic group represented by X is preferably an aromatic hydrocarbon group. Examples of the aromatic hydrocarbon group include a benzene ring, a naphthalene ring, and a phenanthrene ring.

When a tetravalent organic group represented by X contains aromatic rings, each aromatic ring may include a substituent or may be unsubstituted. Examples of a substituent of an aromatic ring include an alkyl group, a fluorine atom, an alkyl halide group, a hydroxyl group, and an amino group.

When a tetravalent organic group represented by X contains a benzene ring, the tetravalent organic group represented by X preferably contains from one to four benzene rings, more preferably contains from one to three benzene rings, and still more preferably contains one or two benzene rings.

When the tetravalent organic group represented by X contains two or more benzene rings, each benzene ring may be linked by a single bond or by a linking group such as an alkylene group, alkylene halide group, carbonyl group, sulfonyl group, an ether bond (—O—), a sulfide bond (—S—), a silylene bond (—Si(R^{A})₂— in which each of the two R^{A}s independently represents a hydrogen atom, an alkyl group, or a phenyl group), or a siloxane bond (—O—(Si(R^{B})₂—O—)ₙ in which each of the two R^{B}s independently represents a hydrogen atom, an alkyl group or a phenyl group, and n is an integer of 1 or 2 or more), a conjugated linking group which is a combination of at least two of these linking groups, or the like. Two benzene rings may be joined in two positions by at least one of a single bond or a linking group to form a 5- or 6-membered ring containing a linking group between the two benzene rings.

In Formula (1), the —COOR⁶ group and the —CONH— group are preferably in the ortho position with each other, or the —COOR⁷ group and the —CO— group are preferably in the ortho position with each other.

Specific examples of the tetravalent organic group represented by X include groups represented by the following Formula (A) to Formula (F). Among these, from the viewpoint of obtaining an insulating film with excellent flexibility and more reduced generation of a void at a bonding interface, a group represented by the following Formula (E) is preferable, a group represented by the following Formula (E) in which C contains an ether bond is more preferable, and an ether bond is still more preferable. The following Formula (F) is a structure in which C in the following Formula (E) is a single bond.

The disclosure is not limited to the following specific examples.

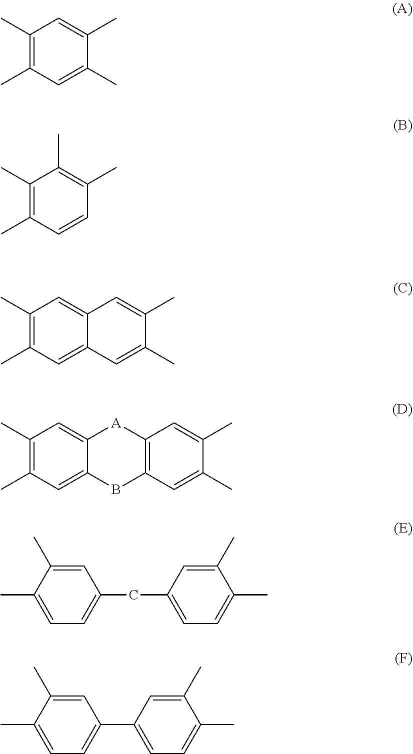

In Formula (D), Each of A and B is independently a single bond or a divalent group not conjugated to a benzene ring. However, not both A and B are a single bond. Examples of the divalent group not conjugated to a benzene ring include a methylene group, a methylene halide group, a methyl methylene halide group, a carbonyl group, a sulfonyl group, an ether bond (—O—), a sulfide bond (—S—), and a silylene bond (—Si(R^{A})₂— in which each of the two R^{A}s independently represents a hydrogen atom, an alkyl group, or a phenyl group). Among them, each of A and B is preferably independently a methylene group, a bis(trifluoromethyl)methylene group, a difluoromethylene group, an ether bond, a sulfide bond, or the like, and more preferably an ether bond.

In Formula (E), C represents a single bond, an alkylene group, an alkylene halide group, a carbonyl group, a sulfonyl group, an ether bond (—O—), a sulfide bond (—S—), a phenylene group, an ester bond (—O—C(═O)—), a silylene bond (—Si(R^{A})₂— in which each of the two R^{A}s independently represents a hydrogen atom, an alkyl group, or a phenyl group), a siloxane bond (—O—(Si(R^{B})₂—O—)ₙ in which each of the two R^{B}s independently represents a hydrogen atom, an alkyl group or a phenyl group, and n is an integer of 1 or 2 or more), or a divalent group combining at least two of these. C preferably contains an ether bond, and is preferably an ether bond.

C may be a structure represented by the following Formula (C1).

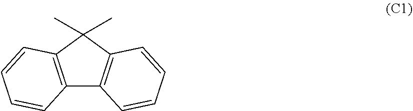

An alkylene group represented by C in Formula (E) is preferably an alkylene group having from 1 to 10 carbon atoms, more preferably an alkylene group having from 1 to 5 carbon atoms, and still more preferably an alkylene group having 1 or 2 carbon atoms.

Examples of an alkylene group represented by C in Formula (E) include: a linear alkylene group such as a methylene group, an ethylene group, a trimethylene group, a tetramethylene group, a pentamethylene group, or a hexamethylene group; and a branched chain alkylene group such as a methylmethylene group, a methylethylene group, an ethylmethylene group, a dimethylmethylene group, a 1,1-dimethylethylene group, a 1-methyltrimethylene group, a 2-methyltrimethylene group, an ethylethylene group, a 1-methyltetramethylene group, a 2-methyltetramethylene group, a 1-ethyltrimethylene group, a 2-ethyltrimethylene group, a 1,1-dimethyltrimethylene group, a 1,2-dimethyltrimethylene group, a 2,2-dimethyltrimethylene group, a 1-methylpentamethylene group, a 2-methylpentamethylene group, a 3-methylpentamethylene group, a 1-ethyltetramethylene group, a 2-ethyltetramethylene group, a 1,1-dimethyltetramethylene group, a 1,2-dimethyltetramethylene group, a 2,2-dimethyltetramethylene group, a 1,3-dimethyltetramethylene group, a 2,3-dimethyltetramethylene group, or a 1,4-dimethyltetramethylene group. Among these, a methylene group is preferable.

An alkylene halide group represented by C in Formula (E) is preferably an alkylene halide group having from 1 to 10 carbon atoms, more preferably an alkylene halide group having from 1 to 5 carbon atoms, and still more preferably an alkylene halide group having from 1 to 3 carbon atoms.

Specific examples of an alkylene halide group represented by C in Formula (E) include an alkylene group in which at least one hydrogen atom in the alkylene group represented by C in Formula (E) above is substituted with a halogen atom such as a fluorine atom or a chlorine atom. Among these, a fluoromethylene group, a difluoromethylene group, a hexafluorodimethylmethylene group, or the like is preferable.

An alkyl group represented by R A or R B contained in the above-described silylene bond or siloxane bond is preferably an alkyl group having from 1 to 5 carbon atoms, more preferably an alkyl group having from 1 to 3 carbon atoms, and still more preferably an alkyl group having from 1 to 2 carbon atoms. Specific examples of an alkyl group represented by R A or R B include a methyl group, an ethyl group, an n-propyl group, an isopropyl group, an n-butyl group, an isobutyl group, an s-butyl group, and a t-butyl group.

Specific examples of a tetravalent organic group represented by X may be a group represented by the following Formula (J) to Formula (0).

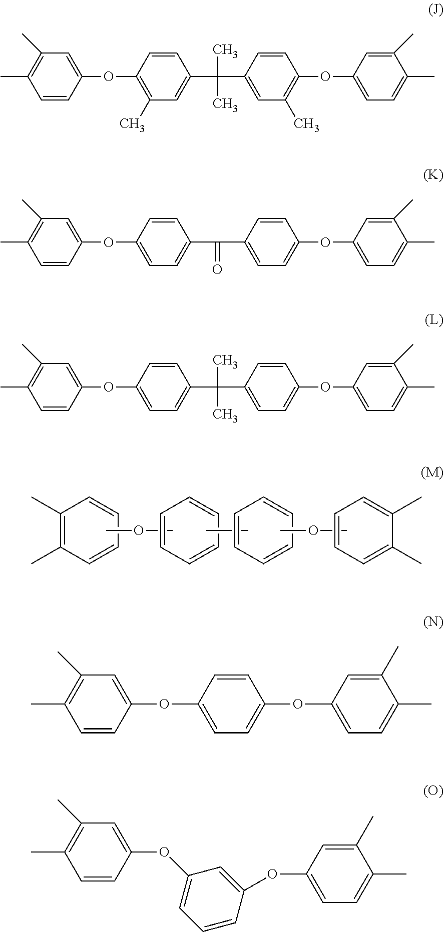

In Formula (1), the number of carbon atoms of a divalent organic group represented by Y is preferably from 4 to 25, more preferably from 6 to 20, and still more preferably from 12 to 18.

A skeleton of a divalent organic group represented by Y may be the same as a skeleton of a tetravalent organic group represented by X, and a preferable skeleton of a divalent organic group represented by Y may be the same as a preferable skeleton of a tetravalent organic group represented by X. The skeleton of a divalent organic group represented by Y may be a structure of a tetravalent organic group represented by X, which is substituted at two bonding positions with an atom (for example, a hydrogen atom) or a functional group (for example, an alkyl group).

A divalent organic group represented by Y may be a divalent aliphatic group or a divalent aromatic group. From the viewpoint of heat resistance, the divalent organic group represented by Y is preferably a divalent aromatic group. Examples of the divalent aromatic group include a divalent aromatic hydrocarbon group (for example, the number of carbon atoms constituting the aromatic ring is from 6 to 20), and a divalent aromatic heterocyclic group (for example, the number of atoms constituting the heterocyclic ring is from 5 to 20), and a divalent aromatic hydrocarbon group is preferable.

Specific examples of the divalent aromatic group represented by Y include groups represented by the following Formula (G) to Formula (I). Among these, from the viewpoint of obtaining an insulating film with excellent flexibility and more suppressed generation of a void at a bonding interface, a group represented by the following Formula (H) is preferable, a group represented by the following Formula (H) in which D contains an ether bond is more preferable, and an ether bond is still more preferable.

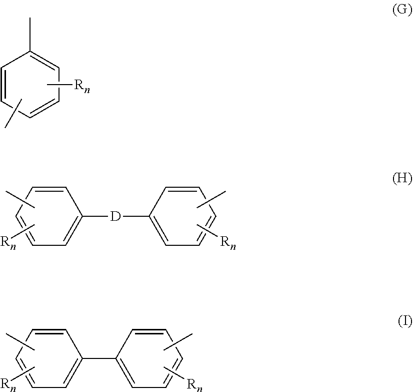

In Formula (G) to Formula (I), R independently represents an alkyl group, an alkoxy group, an alkyl halide group, a phenyl group, or a halogen atom, and n independently represents an integer from 0 to 4.

In Formula (H), D represents a single bond, an alkylene group, an alkylene halide group, a carbonyl group, a sulfonyl group, an ether bond (—O—), a sulfide bond (—S—), a phenylene group, an ester bond (—O—C(═O)—), a silylene bond (—Si(R^{A})₂— in which each of the two R^{A}s independently represents a hydrogen atom, an alkyl group, or a phenyl group), a siloxane bond (—O—(Si(R^{B})₂—O—)ₙ in which each of the two les independently represents a hydrogen atom, an alkyl group or a phenyl group, and n is an integer of 1 or 2 or more), or a divalent group combining at least two of these. D may be a structure represented by the following Formula (C1). Specific examples of D in Formula (H) are the same as specific examples of C in Formula (E).

D in Formula (H) is preferably an ether bond, a group containing an ether bond and a phenylene group, a group containing an ether bond, a phenylene group, and an alkylene group, or the like.

An alkyl group represented by R in Formula (G) to Formula (I) is preferably an alkyl group having from 1 to 10 carbon atoms, more preferably an alkyl group having from 1 to 5 carbon atoms, and still more preferably an alkyl group having 1 or 2 carbon atoms.

Specific examples of the alkyl group represented by R in Formula (G) to Formula (I) include a methyl group, an ethyl group, an n-propyl group, an isopropyl group, an n-butyl group, an isobutyl group, an s-butyl group, and a t-butyl group.

An alkoxy group represented by R in Formula (G) to Formula (I) is preferably an alkoxy group having from 1 to 10 carbon atoms, more preferably an alkoxy group having from 1 to 5 carbon atoms, and still more preferably an alkoxy group having from 1 or 2 carbon atoms.

Specific examples of an alkoxy group represented by R in Formula (G) to Formula (I) include a methoxy group, an ethoxy group, an n-propoxy group, an isopropoxy group, an n-butoxy group, an isobutoxy group, an s-butoxy group, and a t-butoxy group.

An alkyl halide group represented by R in Formula (G) to Formula (I) is preferably an alkyl halide group having from 1 to 5 carbon atoms, more preferably an alkyl halide group having from 1 to 3 carbon atoms, and still more preferably an alkyl halide group having from 1 or 2 carbon atoms.

Specific examples of an alkyl halide group represented by R in Formula (G) to Formula (I) include an alkyl group in which at least one hydrogen atom in the alkyl group represented by R in Formula (G) to Formula (I) is substituted with a halogen atom such as a fluorine atom or a chlorine atom. Among them, a fluoromethyl group, a difluoromethyl group, a trifluoromethyl group, or the like is preferable.

Each of n in Formula (G) to Formula (I) is independently preferably from 0 to 2, more preferably from 0 to 1, and still more preferably from 0.

Specific examples of a divalent aliphatic group represented by Y include a linear or branched chain alkylene group, a cycloalkylene group, a divalent group having a polyalkylene oxide structure, and a divalent group having a polysiloxane structure.

The number of carbon atoms of a linear or branched chain alkylene group represented by Y is preferably an alkylene group having from 1 to 20 carbon atoms, more preferably an alkylene group having from 1 to 15 carbon atoms, and still more preferably an alkylene group having from 1 to 10 carbon atoms.

Specific examples of an alkylene group represented by Y include a tetramethylene group, a hexamethylene group, a heptamethylene group, an octamethylene group, a nonamethylene group, a decamethylene group, an undecamethylene group, a dodecamethylene group, a 2-methylpentamethylene group, a 2-methylhexamethylene group, a 2-methylheptamethylene group, a 2-methyloctamethylene group, a 2-methylnonamethylene group, and a 2-methyldecamethylene group.

A cycloalkylene group represented by Y is preferably a cycloalkylene group having from 3 to 10 carbon atoms, and more preferably a cycloalkylene group having from 3 to 6 carbon atoms.

Specific examples of a cycloalkylene group represented by Y include a cyclopropylene group and a cyclohexylene group.

A unit structure included in a divalent group having a polyalkylene oxide structure represented by Y is preferably an alkylene oxide structure having from 1 to 10 carbon atoms, more preferably an alkylene oxide structure having from 1 to 8 carbon atoms, and still more preferably an alkylene oxide structure having from 1 to 4 carbon atoms. Among others, the polyalkylene oxide structure is preferably a polyethylene oxide structure or a polypropylene oxide structure. An alkylene group in an alkylene oxide structure may be linear or branched. The unit structure in a polyalkylene oxide structure may be of one kind or of two or more kinds.

Examples of a divalent group having a polysiloxane structure represented by Y include a divalent group having a polysiloxane structure in which a silicon atom in the polysiloxane structure is bonded to a hydrogen atom, an alkyl group having from 1 to 20 carbon atoms, or an aryl group having from 6 to 18 carbon atoms.

Specific examples of an alkyl group having from 1 to 20 carbon atoms bonded to a silicon atom in a polysiloxane structure include a methyl group, an ethyl group, an n-propyl group, an isopropyl group, an n-butyl group, a t-butyl group, an n-octyl group, a 2-ethylhexyl group, and an n-dodecyl group. Among them, a methyl group is preferable.

An aryl group having from 6 to 18 carbon atoms bonded to a silicon atom in a polysiloxane structure may be unsubstituted or substituted with a substituent. When an aryl group has a substituent, specific examples of the substituent include a halogen atom, an alkoxy group, and a hydroxy group. Specific examples of an aryl group having from 6 to 18 carbon atoms include a phenyl group, a naphthyl group, and a benzyl group. Among them, a phenyl group is preferable.

An alkyl group having from 1 to 20 carbon atoms or an aryl group having from 6 to 18 carbon atoms in a polysiloxane structure may be of one kind or of two or more kinds.

A silicon atom constituting a divalent group having a polysiloxane structure represented by Y may be bonded to an NH group in Formula (1) via an alkylene group such as a methylene group or an ethylene group, or an arylene group such as a phenylene group.

A group represented by Formula (G) is preferably a group represented by the following Formula (G′), a group represented by Formula (H) is preferably a group represented by the following Formula (H′) or Formula (H″), or a group represented by Formula (I) is preferably a group represented by the following Formula (I′).

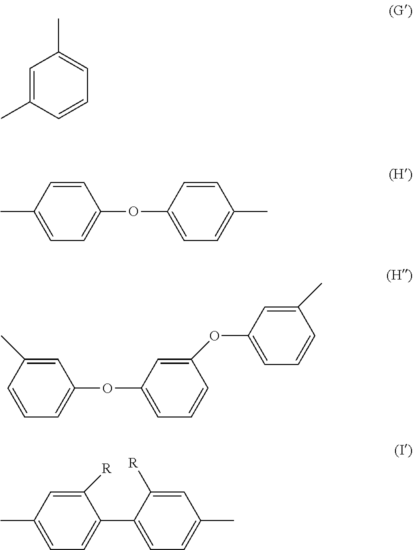

In Formula (I′), each R independently represents an alkyl group, an alkoxy group, an alkyl halide group, a phenyl group, or a halogen atom. R is preferably an alkyl group, and more preferably a methyl group.

The combination of a tetravalent organic group represented by X and a divalent organic group represented by Y in Formula (1) is not particularly limited. Examples of the combination of a tetravalent organic group represented by X and a divalent organic group represented by Y include: a combination of a group represented by Formula (E) for X and a group represented by Formula (H) for Y; and a combination of a group represented by Formula (E) for X and a group represented by Formula (I) for Y.

Each of R⁶ and R⁷ independently represents a hydrogen atom or a monovalent organic group. The monovalent organic group is preferably an aliphatic hydrocarbon group having from 1 to 4 carbon atoms or an organic group having an unsaturated double bond, and more preferably any of a group represented by the following Formula (2), an ethyl group, an isobutyl group, or a t-butyl group, and still more preferably includes an aliphatic hydrocarbon group having 1 or 2 carbon atoms or a group represented by the following Formula (2), and particularly preferably includes a group represented by the following Formula (2). In particular, when a monovalent organic group includes an organic group containing an unsaturated double bond, preferably a group represented by the following Formula (2), the f-ray transmittance tends to be high and a favorable cured product can be formed even when cured at low temperatures of 400° C. or less.

Specific examples of an aliphatic hydrocarbon group having from 1 to 4 carbon atoms include a methyl group, an ethyl group, an n-propyl group, an isopropyl group, an n-butyl group, and a t-butyl group, and among these, an ethyl group, an isobutyl group, or a t-butyl group is preferable.

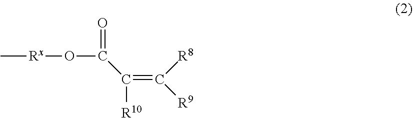

In Formula (2), each of R⁸ to R¹⁰ independently represents a hydrogen atom or an aliphatic hydrocarbon group having from 1 to 3 carbon atoms, and R^{x} represents a divalent linking group.

The number of carbon atoms of an aliphatic hydrocarbon group represented by R⁸ to R¹⁰ in Formula (2) is from 1 to 3, and is preferably 1 or 2. Specific examples of an aliphatic hydrocarbon group represented by R⁸ to R¹⁰ include a methyl group, an ethyl group, an n-propyl group, and an isopropyl group, and a methyl group is preferable.

As a combination of R⁸ to R¹⁰ in Formula (2), a combination where R⁸ and R⁹ are a hydrogen atom and R¹⁰ is a hydrogen atom or a methyl group is preferable.

R^{x} in Formula (2) is a divalent linking group, and preferably a hydrocarbon group having from 1 to 10 carbon atoms. Examples of a hydrocarbon group having from 1 to 10 carbon atoms include a linear or branched chain alkylene group.

The number of carbon atoms in R^{x} is preferably from 1 to 10, more preferably from 2 to 5, and still more preferably from 2 or 3.

In Formula (1), at least one of R⁶ or R⁷ is preferably a group represented by Formula (2), and more preferably both R⁶ and R⁷ are a group represented by Formula (2).

When (A) a component includes a compound containing a structural unit represented by the above-described Formula (1), the ratio of R⁶ and R⁷ that are groups represented by Formula (2) to the total of R⁶ and R⁷ of all structural units contained in the compound is preferably 60% by mole or more, more preferably 70% by mole or more, and still more preferably 80% by mole or more. The upper limit is not particularly limited, and may be 100% by mole.

The above-described ratio may be from 0% by mole to less than 60% by mole.

A group represented by Formula (2) is preferably a group represented by the following Formula (2′).

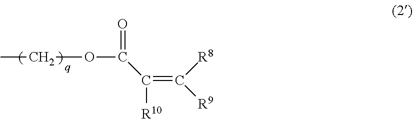

In Formula (2′), each of R⁸ to R¹⁰ independently represents a hydrogen atom or an aliphatic hydrocarbon group having from 1 to 3 carbon atoms, and q represents an integer from 1 to 10.

In Formula (2′), q is an integer from 1 to 10, and is preferably an integer from 2 to 5, and more preferably 2 or 3.

The content of a structural unit represented by Formula (1) in a compound containing the structural unit represented by Formula (1), with respect to the total structural unit, is preferably 60% by mole or more, more preferably 70% by mole or more, and still more preferably 80% by mole or more. The upper limit of the above-described content is not particularly limited, and may be 100% by mole.

(A) a component may be synthesized using tetracarboxylic dianhydride and a diamine compound. In this case, in Formula (1), X corresponds to a residue derived from tetracarboxylic dianhydride, and Y corresponds to a residue derived from a diamine compound. (A) the component may be synthesized using tetracarboxylic acid instead of tetracarboxylic dianhydride.

Specific examples of tetracarboxylic dianhydride include pyromellitic dianhydride, 2,3,6,7-naphthalenetetracarboxylic dianhydride, 3,3′,4,4′-biphenyltetracarboxylic dianhydride, 3,3′,4,4′-benzophenonetetracarboxylic dianhydride, 1,2,5,6-naphthalenetetracarboxylic dianhydride, 2,3,5,6-pyridinetetracarboxylic dianhydride, 1,4,5,8-naphthalenetetracarboxylic dianhydride, 3,4,9,10-perylenetetracarboxylic dianhydride, m-terphenyl-3,3′,4,4′-tetracarboxylic dianhydride, p-terphenyl-3,3′,4,4′-tetracarboxylic dianhydride, 1,1,1,3,3,3-hexafluoro-2,2-bis(2,3-dicarboxyphenyl)propane dianhydride, 1,1,1,3,3,3-hexafluoro-2,2-bis(3,4-dicarboxyphenyl)propane dianhydride, 2,2-bis(2,3-dicarboxyphenyl)propane dianhydride, 2,2-bis(3,4-dicarboxyphenyl)propane dianhydride, 2,2-bis{4′-(2,3-dicarboxyphenoxy)phenyl}propane dianhydride, 2,2-bis{4′-(3,4-dicarboxyphenoxy)phenyl}propane dianhydride, 1,1,1,3,3,3-hexafluoro-2,2-bis{4′-(2,3-dicarboxyphenoxy)phenyl}propane dianhydride, 1,1,1,3,3,3-hexafluoro-2,2-bis{4′-(3,4-dicarboxyphenoxy)phenyl}propane dianhydride, 4,4′-oxydiphthalic dianhydride, 4,4′-sulfonyldiphthalic dianhydride, and 9,9-bis(3,4-dicarboxyphenyl)fluorene dianhydride.

Tetracarboxylic dianhydride may be used singly, or two or more kinds thereof may be used in combination.

Specific examples of diamine compounds include 2,2′-bis(trifluoromethyl)-4,4′-diaminobiphenyl, 2,2′-difluoro-4,4′-diaminobiphenyl, p-phenylenediamine, m-phenylenediamine, p-xylylenediamine, m-xylylenediamine, 1,5-diaminonaphthalene, benzidine, 4,4′-diaminodiphenyl ether, 3,4′-diaminodiphenyl ether, 3,3′-diaminodiphenyl ether, 2,4′-diaminodiphenyl ether, 2,2′-diaminodiphenyl ether, 4,4′-diaminodiphenyl sulfone, 3,4′-diaminodiphenyl sulfone, 3,3′-diaminodiphenyl sulfone, 2,4′-diaminodiphenyl sulfone, 2,2′-diaminodiphenyl sulfone, 4,4′-diaminodiphenyl sulfide, 3,4′-diaminodiphenyl sulfide, 3,3′-diaminodiphenyl sulfide, 2,4′-diaminodiphenyl sulfide, 2,2′-diaminodiphenyl sulfide, o-tolidine, o-tolysine sulfone, 4,4′-methylenebis(2,6-diethylaniline), 4,4′-methylenebis(2,6-diisopropylaniline), 2,4-diaminomesitylene, 1,5-diaminonaphthalene, 4,4′-benzophenonediamine, bis-{4-(4′-aminophenoxy)phenyl}sulfone, 2,2-bis{4-(4′-aminophenoxy)phenyl}propane, 3,3′-dimethyl-4,4′-diaminodiphenylmethane, 3,3′,5,5′-tetramethyl-4,4′-diaminodiphenylmethane, bis{4-(3′-aminophenoxy)phenyl}sulfone, 2,2-bis(4-aminophenyl)propane, 9,9-bis(4-aminophenyl)fluorene, 1,3-bis(3-aminophenoxy)benzene, 1,4-diaminobutane, 1,6-diaminohexane, 1,7-diaminoheptane, 1,8-diaminooctane, 1,9-diaminononane, 1,10-diaminodecane, 1,11-diaminoundecane, 1,12-diaminododecane, 2-methyl-1,5-diaminopentane, 2-methyl-1,6-diaminohexane, 2-methyl-1,7-di aminoheptane, 2-methyl-1,8-diaminooctane, 2-methyl-1,9-diaminononane, 2-methyl-1,10-diaminodecane, 1,4-cyclohexanediamine, 1,3-cyclohexanediamine, and diaminopolysiloxane. As a diamine compound, m-phenylenediamine, 4,4′-diaminodiphenyl ether, or 1,3-bis(3-aminophenoxy)benzene is preferable.

A diamine compound may be used singly, or two or more kinds thereof may be used in combination.

A compound having a structural unit represented by Formula (1) and at least one of R⁶ or R⁷ in Formula (1) is a monovalent organic group can be obtained, for example, by the following method (a) or (b).

(a) Tetracarboxylic dianhydride (preferably tetracarboxylic dianhydride represented by Formula (8) below) is reacted with a compound represented by R—OH in an organic solvent to form a diester derivative, followed by a condensation reaction of the diester derivative with a diamine compound represented by H₂N—Y—NH₂.
(b) A polyamide acid solution is obtained by reacting tetracarboxylic dianhydride with a diamine compound represented by H₂N—Y—NH₂ in an organic solvent, and a compound represented by R—OH is added to the polyamide acid solution to introduce an ester group by reaction in an organic solvent.

Here, Y in a diamine compound represented by H₂N—Y—NH₂ is the same as Y in Formula (1), and specific examples and preferable examples thereof are also the same as those in Formula (1). R in a compound represented by R—OH represents a monovalent organic group, and specific examples and preferable examples thereof are the same as those for R⁶ and R⁷ in Formula (1).

Each of a tetracarboxylic dianhydride represented by Formula (8), a diamine compound represented by H₂N—Y—NH₂, and a compound represented by R—OH may be used singly, or two or more kinds thereof may be used in combination.

Examples of the above-described organic solvent include N-methyl-2-pyrrolidone, γ-butyrolactone, dimethoxyimidazolidinone, and 3-methoxy-N,N-dimethylpropionamide, and among these, 3-methoxy-N,N-dimethylpropionamide is preferable.

A polyimide precursor may be synthesized by allowing a dehydration condensation agent to act on a polyamide acid solution together with a compound represented by R—OH. The dehydration condensation agent preferably includes at least one selected from the group consisting of trifluoroacetic anhydride, N,N′-dicyclohexylcarbodiimide (DCC), and 1,3-diisopropylcarbodiimide (DIC).

The above-described compound in (A) a component can be obtained by acting a compound represented by R—OH on tetracarboxylic dianhydride represented by the following Formula (8) to obtain a diester derivative, then converting the diester derivative to an acid chloride by acting a chlorinating agent such as thionyl chloride, and then reacting the acid chloride with a diamine compound represented by H₂N—Y—NH₂.

The above-described compound in (A) a component can be obtained by allowing a compound represented by R—OH to act on tetracarboxylic dianhydride represented by the following Formula (8) to obtain a diester derivative, and then reacting the diester derivative with a diamine compound represented by H₂N—Y—NH₂ in the presence of a carbodiimide compound.

The above-described compound in (A) a component can be obtained by reacting tetracarboxylic dianhydride represented by the following Formula (8) with a diamine compound represented by H₂N—Y—NH₂ to obtain polyamide acid, followed by isoimidation of the polyamide acid in the presence of a dehydration condensation agent such as trifluoroacetic anhydride, and then by action of a compound represented by R—OH. Alternatively, a compound represented by R—OH may be allowed to act on a portion of tetracarboxylic dianhydride in advance, and the partially esterified tetracarboxylic dianhydride may react with a diamine compound represented by H₂N—Y—NH₂.

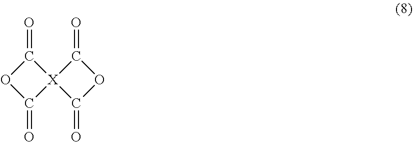

In Formula (8), X is the same as X in Formula (1), and specific examples and preferable examples thereof are also the same.

A compound represented by R—OH used in synthesizing the above-described compound included in (A) a component may be a compound in which a hydroxy group is bonded to R^{X} of a group represented by Formula (2), a compound in which a hydroxy group is bonded to a terminal methylene group of a group represented by Formula (2′), or the like. Specific examples of a compound represented by R—OH include methanol, ethanol, n-propanol, isopropanol, n-butanol, 2-hydroxyethyl methacrylate, 2-hydroxyethyl acrylate, 2-hydroxyethyl methacrylate, 2-hydroxypropyl acrylate, 2-hydroxypropyl methacrylate, 2-hydroxybutyl acrylate, 2-hydroxybutyl methacrylate, 4-hydroxybutyl acrylate, 4-hydroxybutyl methacrylate, and among them, 2-hydroxyethyl methacrylate or 2-hydroxyethyl acrylate is preferable.

The molecular weight of (A) a component is not particularly limited, and for example, the weight average molecular weight is preferably from 10,000 to 200,000, and more preferably from 10,000 to 100,000.

The weight average molecular weight can be measured, for example, by gel permeation chromatography, and can be obtained by conversion using a standard polystyrene calibration curve.

The resin composition of the disclosure may further include a dicarboxylic acid, and (A) a polyimide precursor in the resin composition may have a structure in which a portion of an amino group in (A) the polyimide precursor is reacted with a carboxy group in the dicarboxylic acid. For example, during synthesis of a polyimide precursor, a portion of an amino group in a diamine compound may be reacted with a carboxy group in a dicarboxylic acid.

A dicarboxylic acid may be a dicarboxylic acid containing a (meth)acrylic group, for example, a dicarboxylic acid represented by the following Formula. In this case, when synthesizing (A) a polyimide precursor, by reacting a portion of an amino group of a diamine compound with a carboxy group of a dicarboxylic acid, a methacrylic group derived from the dicarboxylic acid can be introduced into (A) the polyimide precursor.

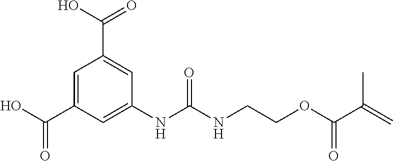 [SMILES: C=C(C)C(=O)OCCNC(=O)Nc1cc(C(=O)O)cc(C(=O)O)c1]

The resin composition of the disclosure may contain a polyimide resin as (A) a component, or may contain the above-described polyimide precursor and polyimide resin.

A polyimide resin is not particularly limited as long as the resin is a high molecular weight compound containing a plurality of structural units including an imide bond, for example, a compound containing a structural unit represented by the following Formula (X) is preferable. As a result, a semiconductor device provided with an insulating film exhibiting high reliability tends to be obtained.

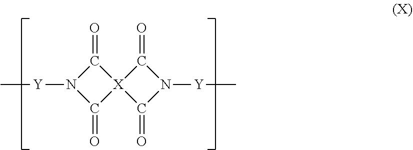

In Formula (X), X represents a tetravalent organic group, and Y represents a divalent organic group. Preferable examples of substituents X and Y in Formula (X) are the same as preferable examples of substituents X and Y in Formula (1) described above.

A combination of a polyimide precursor and a polyimide resin for (A) a component can reduce generation of a volatile product due to dehydration cyclization during imide ring formation, and thus tends to suppress generation of a void. A polyimide resin herein refers to a resin containing an imide skeleton in whole or in part of the resin skeleton. A polyimide resin is preferably soluble in a solvent in a resin composition using a polyimide precursor.

When (A) a component is a polyimide precursor and a polyimide resin, the ratio of the polyimide resin to the total of the polyimide precursor and the polyimide resin may be from 15% by mass to 50% by mass, or from 10% by mass to 20% by mass.

The resin composition of the disclosure may contain a resin component other than (A) the component. For example, from the viewpoint of heat resistance, the resin composition of the disclosure may contain another resin such as a novolac resin, an acrylic resin, a polyether-nitrile resin, a polyethersulfone resin, an epoxy resin, a polyethylene terephthalate resin, a polyethylene naphthalate resin, or a polyvinyl chloride resin. The other resin may be used singly, or two or more kinds thereof may be used in combination.

In the resin composition of the disclosure, the content ratio of (A) a component to the total resin component is preferably from 50% by mass to 100% by mass, more preferably from 70% by mass to 100% by mass, and still more preferably from 90% by mass to 100% by mass.

((B) Solvent)

The resin composition of the disclosure contains (B) a solvent (hereinafter, also referred to as “(B) component”). For example, from the viewpoint of reducing reproductive toxicity and environmental load of the resin composition, (B) the component preferably contains at least one of the group consisting of compounds represented by the following Formula (3) to Formula (7).

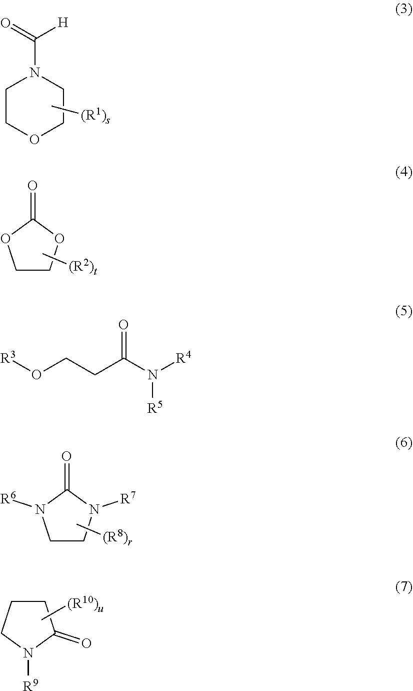

In Formulas (3) to (7), each of R¹, R², R⁸, and R¹⁰ is each independently an alkyl group having from 1 to 4 carbon atoms, and each of R³ to R⁷ and R⁹ is each independently a hydrogen atom or an alkyl group having from 1 to 4 carbon atoms. s is an integer from 0 to 8, t is an integer from 0 to 4, r is an integer from 0 to 4, and u is an integer from 0 to 3. In Formula (3), s is preferably 0.

In Formula (4), an alkyl group having from 1 to 4 carbon atoms in R² is preferably a methyl group or an ethyl group. t is preferably 0, 1 or 2, and more preferably 1.

In Formula (5), an alkyl group having from 1 to 4 carbon atoms in R³ is preferably a methyl group, an ethyl group, a propyl group, or a butyl group. An alkyl group having from 1 to 4 carbon atoms in R 4 and R 5 is preferably a methyl group or an ethyl group.

In Formula (6), an alkyl group having from 1 to 4 carbon atoms in R⁶ to R⁸ is preferably a methyl group or an ethyl group. r is preferably 0 or 1, and more preferably 0.

In Formula (7), an alkyl group having from 1 to 4 carbon atoms in R⁹ and R¹⁰ is preferably a methyl group or an ethyl group. u is preferably 0 or 1, and more preferably 0.

(B) A component may be, for example, at least one of compounds represented by Formulas (4), (5), (6) and (7), and may be a compound represented by Formula (5) or Formula (7).

Specific examples of (B) the component include the following compounds.

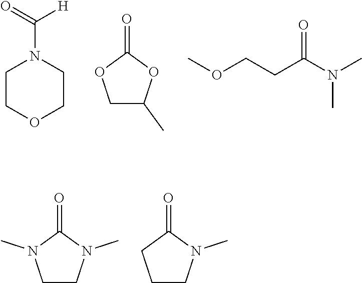

(B) the component in the resin composition of the disclosure is not limited to the above-described compound, and may be any other solvent. (B) the component may be an ester solvent, an ether solvent, a ketone solvent, a hydrocarbon solvent, an aromatic hydrocarbon solvent, a sulfoxide solvent, or the like.

Examples of the ester solvent include ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, γ-butyrolactone, ε-caprolactone, δ-valerolactone, an alkyl alkoxyacetate such as methyl alkoxyacetate, ethyl alkoxyacetate, or butyl alkoxyacetate (for example, methyl methoxyacetate, ethyl methoxyacetate, butyl methoxyacetate, methyl ethoxyacetate, or ethyl ethoxyacetate), a 3-alkoxypropionic acid alkyl ester such as methyl 3-alkoxypropionate or ethyl 3-alkoxypropionate (for example, methyl 3-methoxypropionate, ethyl 3-methoxypropionate, methyl 3-ethoxypropionate, or ethyl 3-ethoxypropionate), a 2-alkoxypropionic acid alkyl ester such as methyl 2-alkoxypropionate, ethyl 2-alkoxypropionate, or propyl 2-alkoxypropionate (for example, methyl 2-methoxypropionate, ethyl 2-methoxypropionate, propyl 2-methoxypropionate, methyl 2-ethoxypropionate, or ethyl 2-ethoxypropionate), methyl 2-alkoxy-2-methylpropionate such as methyl 2-methoxy-2-methylpropionate, ethyl 2-alkoxy-2-methylpropionate such as ethyl 2-ethoxy-2-methylpropionate, methyl pyruvate, ethyl pyruvate, propyl pyruvate, methyl acetoacetate, ethyl acetoacetate, methyl 2-oxobutanoate, and ethyl 2-oxobutanoate.

Examples of the ether solvent include diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate.

Examples of the ketone solvent include methyl ethyl ketone, cyclohexanone, cyclopentanone, 2-heptanone, 3-heptanone, and N-methyl-2-pyrrolidone (NMP).

Examples of the hydrocarbon solvent include limonene.

Examples of the aromatic hydrocarbon solvent include toluene, xylene, and anisole.

Examples of the sulfoxide solvent include dimethyl sulfoxide.

Examples of the solvent for (B) a component preferably include γ-butyrolactone, cyclopentanone, and ethyl lactate.

In the resin composition of the disclosure, from the viewpoint of reducing toxicity such as reproductive toxicity, the content of NMP may be 1% by mass or less with respect to the total amount of the resin composition, and may be 3% by mass or less with respect to the total amount of (A) a component.

In the resin composition of the disclosure, the content of (B) a component with respect to 100 parts by mass of (A) a component is preferably from 1 part by mass to 10,000 parts by mass, and more preferably from 50 parts by mass to 10,000 parts by mass.

(B) the component preferably contains at least one of a solvent (1), which is at least one selected from the group consisting of compounds represented by Formula (3) to Formula (6) or a solvent (2), which is at least one selected from the group consisting of an ester solvent, an ether solvent, a ketone solvent, a hydrocarbon solvent, an aromatic hydrocarbon solvent, and a sulfoxide solvent.

The content of a solvent (1) with respect to the total of the solvent (1) and the solvent (2) may be from 5% by mass to 100% by mass, or from 5% by mass to 50% by mass.

The content of a solvent (1) with respect to 100 parts by mass of (A) a component may be from 10 parts by mass to 1,000 parts by mass, from 10 parts by mass to 100 parts by mass, or from 10 parts by mass to 50 parts by mass.

The resin composition of the disclosure preferably further includes (C) a photoinitiator and (D) a polymerizable monomer (hereinafter, also referred to as (C) component and (D) component, respectively). The resin composition of the disclosure may further include (E) a thermal polymerization initiator (hereinafter, also referred to as (E) component). Hereinafter, preferable embodiments of (C) a component to (E) a component will be described.

((C) Photoinitiator)

The resin composition of the disclosure preferably includes (C) a photoinitiator. This can reduce the number of processes to prepare an electrode in a process of preparing a semiconductor device, thereby reducing the overall cost of a process of preparing a semiconductor device.

Specific examples of (C) the component include: a benzophenone derivative such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 4-chloro benzophenone, 4,4′-dimethoxybenzophenone, 4,4′-diaminobenzophenone, methyl o-benzoylbenzoate, 4-benzoyl-4′-methyldiphenylketone, dibenzylketone, or fluorenone; an acetophenone derivative such as acetophenone, 2,2-diethoxyacetophenone, 3′-methylacetophenone, 2,2-dimethoxy-2-phenylacetophenone, 2-hydroxy-2-methylpropiophenone, or 1-hydroxycyclohexylphenyl ketone; a thioxanthone derivative such as thioxanthone, 2-methylthioxanthone, 2-isopropylthioxanthone, 2-chlorothioxanthone, or diethylthioxanthone; a benzyl derivative such as benzyl, benzyl dimethyl ketal, or benzyl-β-methoxyethyl acetal; a benzoin derivative such as benzoin, benzoin methyl ether, benzoin ethyl ether, benzoin phenyl ether, methylbenzoin, ethylbenzoin, or propylbenzoin; an oxime derivative such as 1-phenyl-1,2-butanedione-2-(0-methoxycarbonyl)oxime, 1-phenyl-1,2-propanedione-2-(0-methoxycarbonyl)oxime, 1-phenyl-1,2-propane dione-2-(0-ethoxycarbonyl)oxime, 1-phenyl-1,2-propanedione-2-(0-benzoyl)oxime, 1,3-diphenylpropanetrione-2-(0-ethoxycarbonyl)oxime, 1-phenyl-3-ethoxypropanetrione-2-(0-benzoyl)oxime, 1,2-octanedione, or 1-[4-(phenylthio)phenyl]-,2-(O-benzoyloxime); an N-arylglycine such as N-phenylglycine; a peroxide such as benzoyl perchloride; an aromatic biimidazole such as 2-(o-chlorophenyl)-4,5-diphenylimidazole dimer, 2-(o-chlorophenyl)-4,5-di(methoxyphenyl)imidazole dimer, 2-(o-fluorophenyl)-4,5-diphenylimidazole dimer, or 2-(o- or p-methoxyphenyl)-4,5-diphenylimidazole dimer; an acylphosphine oxide derivative such as 2,4,6-trimethylbenzoyl-diphenylphosphine oxide and bis(2,4,6-trimethylbenzoyl)phenylphosphine oxide, Irgacure OXE03 (manufactured by BASF), and Irgacure OXE04 (manufactured by BASF).

(C) the component may be used singly, or two or more kinds thereof may be used in combination.

Among them, an oxime compound derivative is preferable from the viewpoint of high reactivity and high sensitivity as well as not containing metal elements.

When the resin composition of the disclosure contains (C) a component, from the viewpoint of facilitating uniform photocrosslinking in the film thickness direction, the content of (C) the component with respect to 100 parts by mass of (A) the component is preferably from 0.1 parts by mass to 20 parts by mass, more preferably from 0.1 parts by mass to 10 parts by mass, and still more preferably from 0.1 parts by mass to 6 parts by mass.

From the viewpoint of improving photosensitive properties, the resin compositions of the disclosure may contain an antireflection agent that reduces reflected light from the substrate direction.

((D) Polymerizable Monomer)

The resin composition of the disclosure preferably includes (D) a polymerizable monomer. (D) the component preferably contains at least one group containing a polymerizable unsaturated double bond, and from the viewpoint of suitable polymerization by combination with a photoinitiator, the component more preferably contains at least one (meth)acrylic group. From the viewpoint of improving crosslink density and photosensitivity, it is preferable to include from 2 to 6 groups containing a polymerizable unsaturated double bond, and it is more preferable to include from 2 to 4 such groups.

The polymerizable monomer may be used singly, or two or more kinds thereof may be used in combination.

The polymerizable monomer containing a (meth)acrylic group is not particularly limited, and examples thereof include diethylene glycol diacrylate, triethylene glycol diacrylate, tetraethylene glycol diacrylate, diethylene glycol dimethacrylate, triethylene glycol dimethacrylate, tetraethylene glycol dimethacrylate, 1,4-butanediol diacrylate, 1,6-hexanediol diacrylate, 1,4-butanediol dimethacrylate, 1,6-hexanediol dimethacrylate, trimethylolpropane diacrylate, trimethylolpropane triacrylate, trimethylolpropane dimethacrylate, trimethylolpropane trimethacrylate, pentaerythritol triacrylate, pentaerythritol tetra Acrylates, pentaerythritol trimethacrylate, pentaerythritol tetramethacrylate, dipentaerythritol hexaacrylate, dipentaerythritol hexamethacrylate, ethoxylated pentaerythritol tetraacrylate, ethoxylated isocyanuric acid triacrylate, ethoxylated isocyanuric acid trimethacrylate, acryloyloxyethyl isocyanurate, methacryloyloxyethyl isocyanurate, 2-hydroxyethyl (meth)acrylate, 1,3-bis((meth)acryloyloxy)-2-hydroxypropane, ethylene oxide (EO)-modified bisphenol A diacrylate, and ethylene oxide (EO)-modified bisphenol A dimethacrylate.

A polymerizable monomer other than polymerizable monomer containing a (meth)acrylic group is not particularly limited, and examples thereof include styrene, divinylbenzene, 4-vinyltoluene, 4-vinylpyridine, N-vinylpyrrolidone, methylenebisacrylamide, N,N-dimethylacrylamide, and N-methylolacrylamide.

(D) the component is not limited to a compound containing a group containing a polymerizable unsaturated double bond, and may be a compound containing a polymerizable group (for example, an oxirane ring) other than an unsaturated double bond group.

When the resin composition of the disclosure contains (D) a component, the content of (D) the component is not particularly limited, and is, with respect to 100 parts by mass of (A) the component, preferably from 1 part by mass to 100 parts by mass, more preferably from 1 part by mass to 75 parts by mass, and still more preferably from 1 part by mass to 50 parts by mass.

((E) Thermal Polymerization Initiator)

The resin composition of the disclosure preferably contains (E) a thermal polymerization initiator from the viewpoint of improving the properties of a cured product.

Examples of (E) components include: a ketone peroxide such as methyl ethyl ketone peroxide; a peroxyketal such as 1,1-di(t-hexylperoxy)-3,3,5-trimethylcyclohexane, 1,1-di(t-hexylperoxy)cyclohexane, or 1,1-di(t-butylperoxy)cyclohexane; a hydroperoxide such as 1,1,3,3-tetramethylbutyl hydroperoxide, cumene hydroperoxide, p-menthane hydroperoxide, or diisopropylbenzene hydroperoxide; a dialkyl peroxide such as dicumyl peroxide or di-t-butyl peroxide; a diacyl peroxide such as dilauroyl peroxide or dibenzoyl peroxide; a peroxydicarbonate such as di(4-t-butylcyclohexyl)peroxydicarbonate or di(2-ethylhexyl)peroxydicarbonate; a peroxyester such as t-butyl peroxy-2-ethylhexanoate, t-hexyl peroxy isopropyl monocarbonate, t-butyl peroxybenzoate, or 1,1,3,3-tetramethylbutyl peroxy-2-ethylhexanoate; and bis(1-phenyl-1-methylethyl)peroxide. The thermal polymerization initiator may be used singly, or two or more kinds thereof may be used in combination.

When the resin composition of the disclosure contains (E) a component, the content of (E) the component with respect to 100 parts by mass of a polyimide precursor may be from 0.1 parts by mass to 20 parts by mass, from 1 part by mass to 15 parts by mass, or from 5 parts by mass to 10 parts by mass.

((F) Polymerization Inhibitor)

The resin composition of the disclosure may contain (F) a polymerization inhibitor (hereinafter, also referred to as “(F) component”) from the viewpoint of ensuring favorable storage stability. Examples of the polymerization inhibitor include a radical polymerization inhibitor and a radical polymerization retarder.

Examples of (F) the component include p-methoxyphenol, diphenyl-p-benzoquinone, benzoquinone, hydroquinone, pyrogallol, phenothiazine, resorcinol, ortho-dinitrobenzene, para-dinitrobenzene, meta-dinitrobenzene, phenanthraquinone, N-phenyl-2-naphthylamine, cupferron, 2,5-toluquinone, tannic acid, parabenzylaminophenol, a nitrosamine, and a hindered phenol compound. The polymerization inhibitor may be used singly, or two or more kinds thereof may be used in combination. A combination of two or more kinds of polymerization inhibitors tends to facilitate adjustment of photosensitive properties due to differences in reactivity. A hindered phenol compound may have both a function of a polymerization inhibitor and a function of an antioxidant as described below, or the compound may have either one of the functions.

The hindered phenol compound is not particularly limited, and examples thereof include 2,6-di-t-butyl-4-methylphenol, 2,5-di-t-butyl-hydroquinone, octadecyl-3-(3,5-di-t-butyl-4-hydroxyphenyl)propionate, isooctyl-3-(3,5-di-t-butyl-4-hydroxyphenyl)propionate, 4,4′-methylenebis(2,6-di-t-butylphenol), 4,4′-thio-bis(3-methyl-6-t-butylphenol), 4,4′-butylidene-bis(3-methyl-6-t-butylphenol), tri ethyl ene glycol-bis[3-(3-t-butyl-5-methyl-4-hydroxyphenyl)propionate], 1,6-hexanediol-bis[3-(3,5-di-t-butyl-4-hydroxyphenyl)propionate], 2,2-thio-diethylenebis[3-(3,5-di-t-butyl-4-hydroxyphenyl)propionate], N,N′-hexamethylenebis(3,5-di-t-butyl-4-hydroxy-hydrocinnamamide), 2,2′-methylene-bis(4-methyl-6-t-butylphenol), 2,2′-methylene-bis(4-ethyl-6-t-butyl phenol), pentaerythrityl-tetrakis[3-(3,5-di-t-butyl-4-hydroxyphenyl)propionate], tris-(3,5-di-t-butyl-4-hydroxybenzyl)-isocyanurate, 1,3,5-trim ethyl-2,4,6-tris(3,5-di-t-butyl-4-hydroxybenzyl)benzene, 1,3,5-tris(3-hydroxy-2,6-dimethyl-4-isopropylbenzyl)-1,3,5-triazine-2,4,6-(1H,3H, 5H)-trione, 1,3,5-tris(4-t-butyl-3-hydroxy-2,6-dimethylbenzyl)-1,3,5-triazine-2,4,6-(1H,3H, 5H)-trione, 1,3,5-tris(4-s-butyl-3-hydroxy-2,6-dimethylbenzyl)-1,3,5-triazine-2,4,6-(1H,3H, 5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-tri ethylmethyl-3-hydroxy-2,6-dimethylbenzyl]-1,3,5-triazine-2,4,6-(1H,3H, 5H)-trione, 1,3,5-tris(3-hydroxy-2,6-dimethyl-4-phenylbenzyl)-1,3,5-triazine-2,4,6-(1H,3H, 5H)-trione, 1,3,5-tris(4-t-butyl-3-hydroxy-2,5,6-trimethylbenzyl)-1,3,5-triazine-2,4,6-(1H,3H, 5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H, 3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-6-di ethyl-3-hydroxy-2-methylbenzyl)-1,3,5-triazine-2,4,6-(1H,3H, 5H)-trione, 1,3,5-tris(4-t-butyl-3-hydroxy-2-methylbenzyl)-1,3,5-triazine-2,4,6-(1H,3H, 5H)-trione, 1,3,5-tris(4-t-butyl-3-hydroxy-2,5-dimethylbenzyl)-1,3,5-triazine-2,4,6-(1H,3H, 5H)-trione, 1,3,5-tris(4-t-butyl-5-ethyl-3-hydroxy-2-methylbenzyl)-1,3,5-triazine-2,4,6-(1H,3H, 5H)-trione, and N,N′-hexane-1,6-diylbis[3-(3,5-di-tert-butyl-4-hydroxyphenyl)propionamide].

Among these, N,N′-hexane-1,6-diyl bis[3-(3,5-di-tert-butyl-4-hydroxyphenyl)propionamide] is preferable.

When the resin composition of the disclosure contains (F) a component, from the viewpoint of storage stability of the resin composition and the heat resistance of a resulting cured product, the content of (F) the component with respect to 100 parts by mass of (A) the component is preferably from 0.01 parts by mass to 30 parts by mass, more preferably from parts by mass to 10 parts by mass, and still more preferably from 0.05 parts by mass to 5 parts by mass.

The resin composition of the disclosure may further contain an antioxidant, a coupling agent, a surfactant, a leveling agent, a rust inhibitor, or a nitrogen-containing compound.

(Antioxidant)

The resin composition of the disclosure may contain an antioxidant from the viewpoint of preventing deterioration of adhesion by trapping an oxygen radical and a peroxide radical generated by high temperature storage, reflow processing, and the like. When the resin composition of the disclosure contains an antioxidant, oxidation of an electrode during insulation reliability testing can be reduced.

Specific examples of the antioxidant include the above-described compounds exemplified as hindered phenol compounds, N,N′-bis[2-[2-(3,5-di-tert-butyl-4-hydroxyphenyl)ethylcarbonyloxy]ethyl]oxamide, N,N′-bis-3-(3,5-di-tert-butyl-4′-hydroxyphenyl)propionylhexamethylenediamine, 1,3,5-tris(3-hydroxy-4-tert-butyl-2,6-dimethylbenzyl)-1,3,5-triazine-2,4,6(1H,3H,5H)-trione, and 1,3,5-tris(4-t-butyl-3-hydroxy-2,6-dimethylbenzyl)isocyanuric acid.

The antioxidant may be used singly, or two or more kinds thereof may be used in combination.

When the resin composition of the disclosure contains an antioxidant, the content of the antioxidant with respect to 100 parts by mass of (A) a component is preferably from 0.1 parts by mass to 20 parts by mass, more preferably from 0.1 parts by mass to 10 parts by mass, and still more preferably from 0.1 parts by mass to 5 parts by mass.

(Coupling Agent)

The resin composition of the disclosure may contain a coupling agent. The coupling agent reacts with (A) the component in a heat treatment to cross-link, or the coupling agent itself polymerizes. As a result, adhesion of a resulting cured product to a substrate tends to be further improved.

Specific examples of coupling agents are not particularly limited. Examples of the coupling agent include a silane coupling agent such as 3-aminopropyltrimethoxysilane, N-(2-aminoethyl)-3-aminopropylmethyldimethoxy silane, 3-glycidoxypropylmethyldimethoxysilane, 3-mercaptopropylmethyldimethoxysilane, 3-methacryloxypropyldimethoxymethylsilane, 3-methacryloxypropyltrimethoxysilane, dimethoxymethyl-3-piperidinopropylsilane, diethoxy-3-glycidoxypropylmethylsilane, N-(3-diethoxymethylsilylpropyl)succinimide, N-[3-(triethoxysilyl)propyl]phthalamic acid, benzophenone-3,3′-bis(N-[3-tri ethoxy silyl]propylamide)-4,4′-dicarboxylic acid, benzene-1,4-bis(N-[3-triethoxysilyl]propylamide)-2,5-dicarboxylic acid, 3-(triethoxysilyl)propyl succinic anhydride, N-phenylaminopropyltrimethoxysilane, N,N′-bis(2-hydroxy ethyl)-3-aminopropyltriethoxysilane, or 3-ureidopropyltriethoxysilane; and an aluminum-based adhesion aid such as aluminum tris(ethylacetoacetate), aluminum tris(acetylacetonate), or ethylacetoacetate aluminum diisopropylate.

The coupling agent may be used singly, or two or more kinds thereof may be used in combination.

When the resin composition of the disclosure contains a coupling agent, the content of the coupling agent with respect to 100 parts by mass of (A) a component is preferably from 0.1 parts by mass to 20 parts by mass, more preferably from 0.3 parts by mass to 10 parts by mass, and still more preferably from 1 part by mass to 10 parts by mass.

(Surfactant and Leveling Agent)

The resin composition of the disclosure may include at least one of a surfactant or a leveling agent. By including at least one of a surfactant or a leveling agent in the resin composition, the applicability (for example, reduction of striation (uneven film thickness)), improvement of adhesion, compatibility of a compound in the resin composition, or the like can be enhanced.

Examples of the surfactant or the leveling agent include polyoxyethylene uralyl ether, polyoxyethylene stearyl ether, polyoxyethylene oleyl ether, and polyoxyethylene octyl phenol ether.

The surfactant and the leveling agent may be used singly, or two or more kinds thereof may be used in combination.

When the resin composition of the disclosure contains at least one of a surfactant or a leveling agent, the total content of the surfactant and the leveling agent with respect to 100 parts by mass of (A) a component is preferably from 0.01 parts by mass to 10 parts by mass, more preferably from 0.05 parts by mass to 5 parts by mass, and still more preferably from 0.05 parts by mass to 3 parts by mass.

(Rust Inhibitor)

The resin composition of the disclosure may contain a rust inhibitor from the viewpoint of preventing corrosion of a metal such as copper or a copper alloy, and from the viewpoint of preventing discoloration of such a metal. Examples of a rust inhibitor include an azole compound and a purine derivative.

Specific examples of an azole compound include 1H-triazole, 5-methyl-1H-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, hydroxyphenyltriazole, 1,5-dimethyltriazole, 4,5-diethyl-1H-triazole, 1H-benzotriazole, 2-(5-methyl-2-hydroxyphenyl)benzotriazole, 2-[2-hydroxy-3,5-bis(α,α-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, hydroxyphenylbenzotriazole, tolyl triazole, 5-methyl-1H-benzotriazole, 4-methyl-1H-benzotriazole, 4-carboxy-1H-benzotriazole, 5-carboxy-1H-benzotriazole, 1H-tetrazole, 5-methyl-1H-tetrazole, 5-phenyl-1H-tetrazole, 5-amino-1H-tetrazole, and 1-methyl-1H-tetrazole.

Examples of purine derivatives include purine, adenine, guanine, hypoxanthine, xanthine, theobromine, caffeine, uric acid, isoguanine, 2,6-diaminopurine, 9-methyladenine, 2-hydroxyadenine, 2-methyladenine, 1-methyladenine, N-methyladenine, N,N-dimethyladenine, 2-fluoroadenine, 9-(2-hydroxyethyl)adenine, guanine oxime, N-(2-hydroxyethyl)adenine, 8-aminoadenine, 6-amino-8-phenyl-9H-purine, 1-ethyladenine, 6-ethylaminopurine, 1-benzyladenine, N-methylguanine, 7-(2-hydroxyethyl)guanine, N-(3-chlorophenyl)guanine, N-(3-ethylphenyl)guanine, 2-azaadenine, 5-azaadenine, 8-azaadenine, 8-azaguanine, 8-azapurine, 8-azaxanthin, and 8-azahypoxanthine, and a derivative thereof.

The rust inhibitor may be used singly, or two or more kinds thereof may be used in combination.

When the resin composition of the disclosure contains a rust inhibitor, the content of the rust inhibitor with respect to 100 parts by mass of (A) a component is preferably from 0.01 parts by mass to 10 parts by mass, more preferably from 0.1 parts by mass to 5 parts by mass, and still more preferably from 0.5 parts by mass to 3 parts by mass. In particular, when the content of a rust inhibitor is 0.1 parts by mass or more, application of the resin composition of the disclosure on the surface of copper or a copper alloy prevents discoloration of the surface of the copper or the copper alloy.

The resin composition of the disclosure may contain a nitrogen-containing compound from the viewpoint of accelerating an imidization reaction of (A) a component to obtain a cured product with high reliability.

Specific examples of the nitrogen-containing compound include 2-(methylphenylamino)ethanol, 2-(ethylanilino)ethanol, N-phenyldiethanolamine, N-methylaniline, N-ethylaniline, N,N′-dimethylaniline, N-phenylethanolamine, 4-phenylmorpholine, 2,2′-(4-methylphenylimino)diethanol, 4-aminobenzamide, 2-aminobenzamide, nicotinamide, 4-amino-N-methylbenzamide, 4-aminoacetanilide, and 4-aminoacetophenone, and among them, N-phenyldiethanolamine, N-methylaniline, N-ethylaniline, N,N′-dimethylaniline, N-phenylethanolamine, 4-phenylmorpholine, 2,2′-(4-methylphenylimino)diethanol or the like is preferable. The nitrogen-containing compound may be used singly, or two or more kinds thereof may be used in combination.

The nitrogen-containing compound preferably includes a compound represented by the following Formula (17).

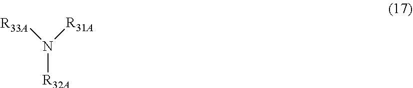

In Formula (17), each of R_{31A} to R_{33A} is each independently a hydrogen atom, a monovalent aliphatic hydrocarbon group, a monovalent aliphatic hydrocarbon group including a hydroxy group, or a monovalent aromatic group, and at least one (preferably one) of R_{31A} to R_{33A} is a monovalent aromatic group. R_{31A} to R_{33A} may form a ring structure between adjacent groups. Examples of the ring structure to be formed include a 5-membered ring, a 6-membered ring, and the like, which may include a substituent such as a methyl group or a phenyl group. A hydrogen atom of a monovalent aliphatic hydrocarbon group may be substituted with a functional group other than a hydroxy group.

In Formula (17), at least one (preferably one) of R_{31A} to R_{33A} is preferably a monovalent aliphatic hydrocarbon group, a monovalent aliphatic hydrocarbon group including a hydroxy group, or a monovalent aromatic group.

In Formula (17), the number of carbon atoms of a monovalent aliphatic hydrocarbon group of R_{31A} to R_{33A} is preferably from 1 to 10, and more preferably from 1 to 6. The monovalent aliphatic hydrocarbon group is preferably a methyl group, an ethyl group, or the like.

A monovalent aliphatic hydrocarbon group including a hydroxy group of R_{31A} to R_{33A} in Formula (17) is preferably a group in which one or more hydroxy groups are bonded to a monovalent aliphatic hydrocarbon group of R_{31A} to R_{33A}, and is more preferably a group in which one to three hydroxy groups are bonded to the aliphatic hydrocarbon group. Specific examples of a monovalent aliphatic hydrocarbon group including a hydroxy group include a methylol group and a hydroxyethyl group, and among them, a hydroxyethyl group is preferable.

Examples of the monovalent aromatic group of R_{31A} to R_{33A} in Formula (17) include a monovalent aromatic hydrocarbon group and a monovalent aromatic heterocyclic group, and a monovalent aromatic hydrocarbon group is preferable. The number of carbon atoms of the monovalent aromatic hydrocarbon group is preferably from 6 to 12, and more preferably from 6 to 10.

Examples of the monovalent aromatic hydrocarbon group include a phenyl group and a naphthyl group.

The monovalent aromatic group of R_{31A} to R_{33A} of Formula (17) may include a substituent. Examples of the substituent include a monovalent aliphatic hydrocarbon group of R_{31A} to R_{33A} of Formula (17) and a group similar to the above-described monovalent aliphatic hydrocarbon group including a hydroxy group of R_{31A} to R_{33A} of Formula (17).

When the resin composition of the disclosure contains a nitrogen-containing compound, the content of the nitrogen-containing compound with respect to 100 parts by mass of (A) a component is preferably from 0.1 parts by mass to 20 parts by mass, and from the viewpoint of storage stability, more preferably from 0.3 parts by mass to 15 parts by mass, and still more preferably from 0.5 parts by mass to 10 parts by mass.

The resin composition of the disclosure includes (A) a component and (B) a component, and includes (C) a component to (F) a component, an antioxidant, a coupling agent, a surfactant, a leveling agent, a rust inhibitor, a nitrogen-containing compound, or the like if necessary, and may include another component and an unavoidable impurity to an extent that does not impair an effect of the disclosure.

For example, 80% by mass or more, 90% by mass or more, 95% by mass or more, 98% by mass or more, or 100% by mass of the resin composition of the disclosure may be composed of:

(A) a component and (B) a component;

(A) a component to (C) a component;

(A) a component to (E) a component;

(A) a component to (F) a component; or

(A) a component to (F) a component and at least one selected from the group consisting of an antioxidant, a coupling agent, a surfactant, a leveling agent, a rust inhibitor, and a nitrogen-containing compound.

<Semiconductor Device>

The semiconductor device of the disclosure is a semiconductor device including: a first semiconductor substrate including a first substrate body, and a first organic insulating film and a first electrode on one side of the first substrate body; and a semiconductor chip including a semiconductor chip substrate body, and an organic insulating film portion and a second electrode provided on one side of the semiconductor chip substrate body, wherein the first organic insulating film of the first semiconductor substrate and the organic insulating film portion of the semiconductor chip are bonded, and the first electrode of the first semiconductor substrate and the second electrode of the semiconductor chip are bonded, and at least one of the first organic insulating film or the organic insulating film portion is an insulating film obtained by curing the resin composition of the disclosure.

Since, in the semiconductor device of the disclosure, at least one of a first organic insulating film or an organic insulating film portion is an insulating film obtained by curing the resin composition of the disclosure, generation of a void at a bonding interface of the insulating film is reduced, and the insulating film has excellent heat resistance. The semiconductor device of the disclosure is produced through a process (1) to a process (5).

<Method for Producing Semiconductor Device>

In the method for producing a semiconductor device of the disclosure, a semiconductor device is produced using the resin composition of the disclosure. Specifically, a semiconductor device can be produced by using the resin composition of the disclosure and performing a process (1) to a process (5).

<Cured Product>

The cured product of the disclosure is obtained by curing the resin composition of the disclosure. A cured product is used, for example, as an insulating film for a semiconductor device.

Hereinafter, with reference to the drawings, one embodiment of the semiconductor device of the disclosure and one embodiment of the method for producing a semiconductor device of the disclosure will be described in detail. In the following description, an identical or equivalent portion is indicated with the same symbol, and a redundant description will be omitted. Unless otherwise specified, the positional relationships of top, bottom, left, right, and the like are based on the positional relationships illustrated in the drawings. Furthermore, the dimensional ratios in the drawings are not limited to the ratios illustrated in the drawings.

(One Example of Semiconductor Device)

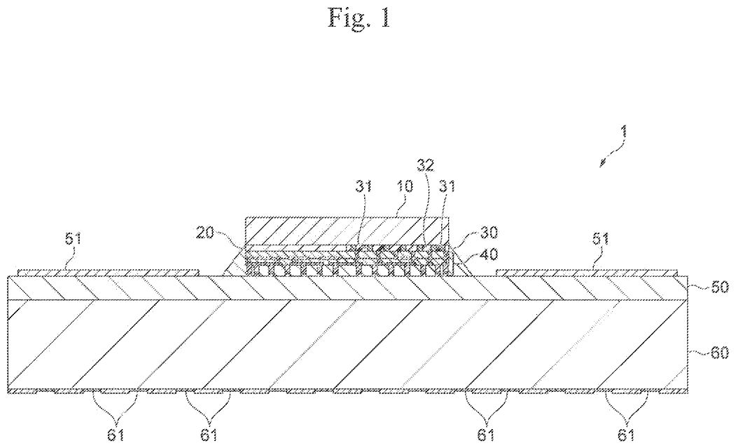

FIG. 1 is a schematic sectional view of an example of the semiconductor device of the disclosure. As illustrated in FIG. 1, a semiconductor device 1 is one example of a semiconductor package, and includes a first semiconductor chip 10 (first semiconductor substrate), a second semiconductor chip 20 (semiconductor chip), a pillar portion 30, a rewiring layer 40, a substrate 50, and a circuit board 60.

The first semiconductor chip 10 is a semiconductor chip such as a large scale integrated circuit (LSI) chip or a complementary metal oxide semiconductor (CMOS) sensor, and has a three-dimensional mounting structure in which the second semiconductor chip 20 is mounted downward. The second semiconductor chip 20 is a semiconductor chip such as an LSI or a memory, and is a chip component with a smaller area in plan view than the first semiconductor chip 10. The second semiconductor chip 20 is chip-to-chip (C2C) bonded to the backside of the first semiconductor chip 10. The first semiconductor chip 10 and the second semiconductor chip 20 are micro bonded by hybrid bonding, the details of which are described below, to each terminal electrode and the surrounding insulating film firmly and without misalignment.

The pillar portion 30 is a connecting portion in which a plurality of pillars 31 formed of a metal such as copper (Cu) are sealed by a resin 32. The plurality of pillars 31 are conductive members extending from the top surface to the bottom surface of the pillar portion 30. The plurality of pillars 31 may have a cylindrical shape with a diameter of from 3 μm to 20 μm (in one example, 5 μm in diameter), for example, and may be arranged in such a manner that the distance between centers of the pillars 31 is 15 μm or smaller. The plurality of pillars 31 make flip chip connections between a terminal electrode on the bottom side of the first semiconductor chip 10 and a terminal electrode on the top side of the rewiring layer 40. By using the pillar portion 30, the semiconductor device 1 can form a connecting electrode without using a technique called through mold via (TMV), in which a hole is drilled in a mold and a solder connection is made. The pillar portion 30, for example, has the same thickness as the second semiconductor chip 20, and is positioned horizontally to the side of the second semiconductor chip 20. A plurality of solder balls may be arranged instead of the pillar portions 30, and the solder balls may electrically connect a terminal electrode on the bottom side of the first semiconductor chip 10 to a terminal electrode on the top side of the rewiring layer 40.

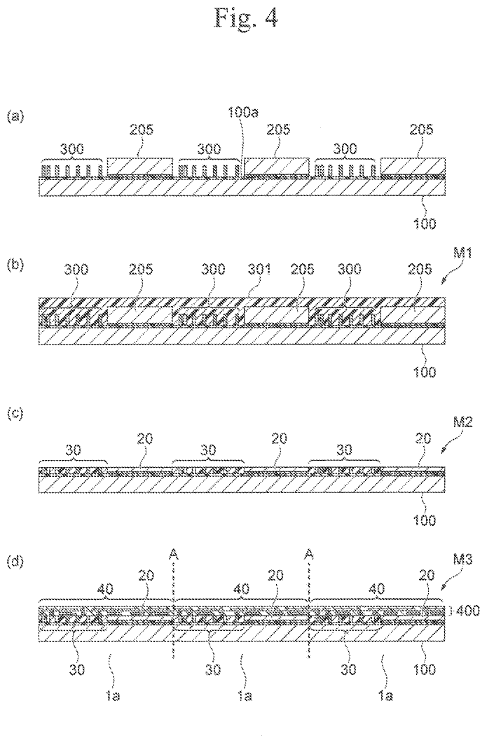

The rewiring layer 40 is a wiring layer having a function of terminal pitch conversion, which is a function of a package substrate, and is a layer in which a rewiring pattern is formed with polyimide, copper wiring, and the like on an insulating film on the bottom side of the second semiconductor chip 20 and on the underside of the pillar portion 30. The rewiring layer 40 is formed in a state in which the first semiconductor chip 10, the second semiconductor chip 20, and the like are inverted upside down (see (d) of FIG. 4).

The rewiring layer 40 electrically connects a terminal electrode on the underside of the second semiconductor chip 20 and a terminal electrode of the first semiconductor chip 10 via the pillar portion 30 to a terminal electrode of the substrate 50. The terminal pitch of the substrate 50 is wider than the terminal pitch of a pillar 31 and the terminal pitch of the second semiconductor chip 20. Various electronic components 51 may be mounted on the substrate 50. When there is a large gap in the terminal pitch between the rewiring layer 40 and the substrate 50, an inorganic interposer or the like may be used between the rewiring layer 40 and the substrate 50 for electrical connection between the rewiring layer 40 and the substrate 50.

Circuit board 60 is a substrate including a first semiconductor chip 10 and a second semiconductor chip 20 mounted thereon and including a plurality of through-hole electrodes therein that are electrically connected to the substrate 50 connected to the first semiconductor chip 10, the second semiconductor chip 20, the electronic components 51, and the like. In the circuit board 60, each terminal electrode of the first semiconductor chip 10 and the second semiconductor chip 20 is electrically connected to a terminal electrode 61 provided on the back surface of the circuit board 60 by the plurality of through-hole electrodes.

(One Example of Method for Producing Semiconductor Device)

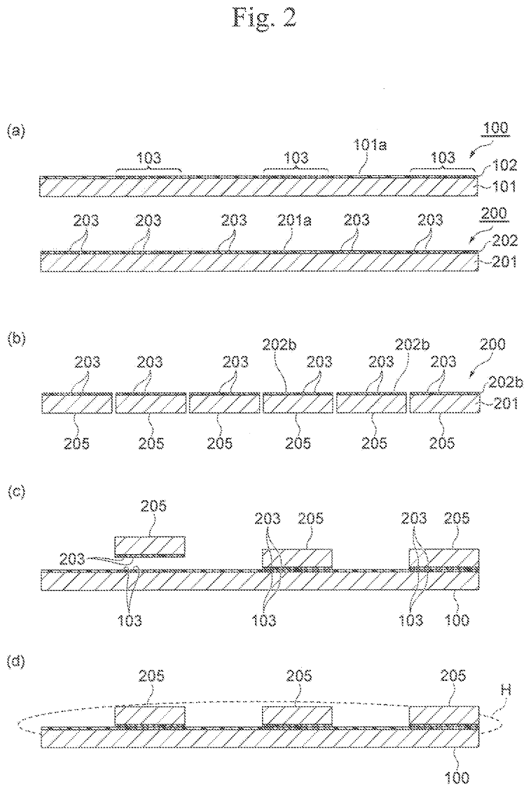

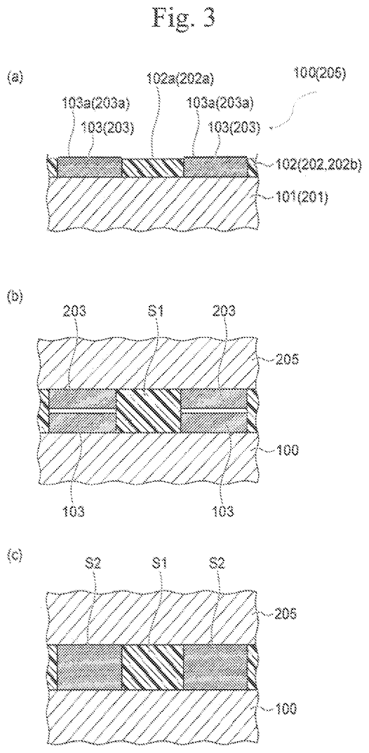

Next, one example of a method for producing the semiconductor device 1 will be described with reference to FIG. 2 to FIG. 4. FIG. 2 is a diagram illustrating a method for producing the semiconductor device illustrated in FIG. 1 in sequence. FIG. 3 is a diagram illustrating a bonding method (hybrid bonding) in the method for producing a semiconductor device illustrated in FIG. 2 in more detail. FIG. 4 is a diagram illustrating a method for producing the semiconductor device illustrated in FIG. 1, illustrating processes after the process illustrated in FIG. 2, in sequence.

The semiconductor device 1 can be produced, for example, through the following process (a) to process (n).

(a) A process of preparing a first semiconductor substrate 100 corresponding to the first semiconductor chip 10.
(b) A process of preparing a second semiconductor substrate 200 corresponding to the second semiconductor chip 20.
(c) A process of polishing the first semiconductor substrate 100.
(d) A process of polishing the second semiconductor substrate 200.
(e) A process of individualizing the second semiconductor substrate 200 to obtain a plurality of semiconductor chips 205.
(f) A process of aligning a terminal electrode 203 of each of a plurality of semiconductor chips 205 with a terminal electrode 103 of the first semiconductor substrate 100.
(g) A process of bonding an insulating film 102 of the first semiconductor substrate 100 and insulating film portions 202b of the plurality of semiconductor chips 205 to each other (see (b) in FIG. 3).
(h) A process of bonding the terminal electrode 103 of the first semiconductor substrate 100 to a terminal electrode 203 of each of the plurality of semiconductor chips 205 (see (c) in FIG. 3).
(i) A process of forming a plurality of pillars 300 (corresponding to the pillar 31) on the connecting surface of the first semiconductor substrate 100 and between the plurality of semiconductor chips 205.
(j) A process of molding a resin 301 on the connecting surface of the first semiconductor substrate 100 in such a manner to cover the semiconductor chip 205 and the pillar 300, thereby obtaining a semi-finished product M1.
(k) A process of grinding and thinning the resin 301 side of the semi-finished product M1 molded in the process (j), thereby obtaining a semi-finished product M2.
(l) A process of forming a wiring layer 400 corresponding to the rewiring layer 40 on the thinned semi-finished product M2 in the process (k).
(m) A process of cutting a semi-finished product M3 on which the wiring layer 400 is formed in the process (1) along a cutting line A in such a manner to obtain semiconductor devices 1.
(n) A process of inverting a semiconductor device 1a individualized in the process (m) and placing the device on the substrate 50 and the circuit board 60 (see FIG. 1).

For example, in the resin composition of the disclosure, the process (1) corresponds to the above-described process (a) and process (c), the process (2) corresponds to the above-described process (b) and process (d), the process (3) corresponds to process (e), the process (4) corresponds to process (g), and the process (5) corresponds to the process (h). Furthermore, the resin composition of the disclosure may be a resin composition for use in preparing an insulating film of at least one of the first organic insulating film or the second organic insulating film in a method for producing a semiconductor device, the method including at least one process corresponding to the process (f) and the processes (i) to (n).

[Process (a) and Process (b)]

The process (a) is a process of preparing the first semiconductor substrate 100, which is a silicon substrate on which an integrated circuit composed of semiconductor elements, wiring connecting the elements, and the like, corresponding to the plurality of first semiconductor chips 10, is formed. In the process (a), as illustrated in (a) of FIG. 2, on one side 101a of the first substrate body 101 made of silicon or the like, the plurality of terminal electrodes 103 (first electrodes) made of copper, aluminum, or the like are provided at predetermined intervals, and an insulating film 102 (first insulating film) that is a cured product obtained by curing the resin composition of the disclosure is provided. The plurality of terminal electrodes 103 may be provided after the insulating film 102 is provided on one side 101a of the first substrate body 101, or the plurality of terminal electrodes 103 may be provided on one side 101a of the first substrate body 101 before the insulating film 102 is provided. In order to form the pillar 300 in the process described below, a predetermined interval is provided between the plurality of terminal electrodes 103, and another terminal electrode (not illustrated) connected to the pillar 300 is formed in between the plurality of terminal electrodes 103.

The process (b) is a process of preparing the second semiconductor substrate 200, which is a silicon substrate on which an integrated circuit including semiconductor elements and wiring connecting the elements, corresponding to the plurality of second semiconductor chips 20, is formed. In the process (b), as illustrated in (b) of FIG. 2, on one side 201a of a second substrate body 201 made of silicon or the like, the plurality of terminal electrodes 203 (a plurality of second electrodes) made of copper, aluminum, or the like are continuously provided at predetermined intervals, and an insulating film 202 (second insulating film) that is a cured product obtained by curing the resin composition of the disclosure is provided. The plurality of terminal electrodes 203 may be provided after the insulating film 202 is provided on one side 201a of the second substrate body 201, or the plurality of terminal electrodes 203 may be provided on one side 201a of the second substrate body 201 before the insulating film 202 is provided.

The configuration is not limited to a configuration in which both the insulating film 102 and the insulating film 202 used in the process (a) and the process (b) are cured products obtained by curing the resin composition of the disclosure, and may also be a configuration in which at least one of the insulating film 102 or the insulating film 202 is a cured product obtained by curing the resin composition of the disclosure. The insulating film other than the cured product does not include a polyimide precursor, and examples thereof include a cured product obtained by curing a resin composition containing an organic material such as polyimide, polyamideimide, benzocyclobutene (BCB), polybenzoxazole (PBO), PBO precursor, or the like. The tensile modulus at 25° C. of the insulating film 102 and the insulating film 202 is preferably 7.0 GPa or less, more preferably 5.0 GPa or less, still more preferably 3.0 GPa or less, particularly preferable 2.0 GPa or less, and further preferably 1.5 GPa or less.

The thermal expansion coefficient of the insulating film 102 and the insulating film 202 is preferably 150 ppm/K or less, more preferably 100 ppm/K or less, and still more preferably 90 ppm/K or less.

The thickness of the insulating film 102 and the insulating film 202 is preferably from μm to 50 μm, and more preferably from 1 μm to 15 μm. This allows the processing time to be reduced in the subsequent polishing process while ensuring the uniformity of the insulating film thickness.

From the viewpoint that operations in the process (c) and the process (d) are easier to perform and these processes can be simplified, it is preferable that at least one of that the polishing rate of the insulating film 102 is from 0.1 to 5 times the polishing rate of the terminal electrode 103 or that the polishing rate of the insulating film 202 is from 0.1 to 5 times the polishing rate of the terminal electrode 203 (preferably both) is satisfied. In one example, when the terminal electrode 103 or 203 is made of copper and the polishing rate of copper is 50 nm/min, the polishing rate of the insulating film 102 or 202 is preferably 200 nm/min or less (4 times or less the polishing rate of copper), more preferably 100 nm/min or less (2 times or less the polishing rate of copper), and still more preferably 50 nm/min or less (the same as or less than the polishing rate of copper).

Next, a method of preparing an insulating film will be described. An insulating film is obtained by curing a resin composition. Examples of the above-described method of preparing an insulating film include: (α) a method including a process of coating and drying a resin composition on a substrate to form a resin film, and a process of heat treating the resin film; and (β) a method including a process of forming a film of a specified thickness using a resin composition on a film with a mold release treatment, then transferring the resin film to the substrate by a laminating method, and a process of heat treating the resin film formed on the substrate after the transfer. From the viewpoint of flatness, the above-described (a) method is preferable.

Examples of a method of applying a resin composition include a spin coating method, an ink-jet method, and a slit-coating method.

In a spin coating method, for example, the above-described resin composition may be spin-coated at a rotational speed of from 300 rpm (revolutions per minute) to 3,500 rpm, preferably from 500 rpm to 1,500 rpm, an acceleration of from 500 rpm/sec to 15,000 rpm/sec, and a rotation time of from 30 seconds to 300 seconds.

A drying process may be included after a resin composition is applied to a support, a film, or the like. Drying may be performed using a hot plate, an oven, or the like. The drying temperature is preferably from 75° C. to 130° C., and from the viewpoint of improving the flatness of an insulating film, the drying temperature is more preferably from 90° C. to 120° C. Drying time is preferably from 30 seconds to 5 minutes.

Drying may be performed two or more times. As a result, a resin film formed from the above-described resin composition in the form of a film can be obtained.

In a slit coating method, for example, the above-described resin composition may be slit coated at a chemical dispensing rate of from 10 μL/sec to 400 μL/sec, a chemical discharge height of from 0.1 μm to 1.0 μm, a stage speed (or chemical dispensing portion speed) of from 1.0 mm/sec. to 50.0 mm/sec, a stage acceleration of from 10 mm/sec to 1,000 mm/sec, a vacuum attained during decompression drying of from 10 Pa to 100 Pa, a decompression drying time of from 30 seconds to 600 seconds, a drying temperature of from 60° C. to 150° C., and a drying time of from 30 seconds to 300 seconds.

The formed resin film may be heat treated. The heating temperature is preferably from 150° C. to 450° C., and more preferably from 150° C. to 350° C. By setting the heating temperature within the above-described range, an insulating film can be suitably prepared while reducing damage to a substrate, a device, or the like and achieving energy saving of a process.

The heating time is preferably 5 hours or less, and more preferably from 30 minutes to 3 hours. By keeping the time of heat treatment within the above-described range, a cross-linking reaction or a dehydration ring-closing reaction can be sufficiently progressed.

The atmosphere for heat treatment may be atmospheric or in an inert atmosphere such as nitrogen, and from the viewpoint of preventing oxidation of a resin film, a nitrogen atmosphere is preferable.

Examples of an apparatus used for heat treatment include a quartz tube furnace, a hot plate, a rapid thermal annealing, a vertical diffusion furnace, an infrared curing furnace, an electron beam curing furnace, and a microwave curing furnace.

In the case of using the resin composition of the disclosure, which is a negative-type photosensitive resin composition or a positive-type photosensitive resin composition, when the plurality of terminal electrodes 203 are provided after the insulating film 202 is provided on one side 201a of the second substrate body 201, for example, a method including: a process of applying a resin composition on a substrate, a process of drying to form a resin film; a process of pattern exposing the resin film and developing the resin film using a developer to obtain a patterned resin film; and a process of heat treating the patterned resin film may be used. As a result, a cured pattern insulating film can be obtained.

Alternatively, when the plurality of terminal electrodes 203 are provided after the insulating film 202 is provided on one side 201a of the second substrate body 201, for example, a method including: a process of applying a resin composition other than the resin composition of the disclosure on a substrate; a process of drying to form a resin film; a process of applying and drying the resin composition of the disclosure, which is a negative-type photosensitive resin composition or a positive-type photosensitive resin composition, on the resin film, then pattern exposing the resin composition, and developing using a developer to obtain a patterned resin film; and a process of heat treating the patterned resin film may be used. As a result, a cured pattern insulating film can be obtained.

Pattern exposure involves, for example, exposure to a predetermined pattern via a photomask.

Examples of an active light beam to be irradiated include an ultraviolet ray such as i-line or broadband, visible light, and radiation, and i-line is preferable. As an exposure apparatus, a parallel exposure machine, a projection exposure machine, a stepper, a scanner exposure machine, or the like can be used.

By developing a film after exposure, a patterned resin film, which is a resin film with a pattern formed thereon, can be obtained. When the resin composition of the disclosure is a negative-type photosensitive resin composition, an unexposed portion is removed with a developer.

For an organic solvent used as a negative-type developer, as a developer, a good solvent for a photosensitive resin film can be used singly, or a good solvent and a poor solvent can be mixed together as appropriate and used.

Examples of the good solvent include N-methyl-2-pyrrolidone, N-acetyl-2-pyrrolidone, N,N-dimethylacetamide, N,N-dimethylformamide, dimethyl sulfoxide, γ-butyrolactone, α-acetyl-γ-butyrolactone, 3-methoxy-N,N-dimethylpropanamide, cyclopentanone, cyclohexanone, and cycloheptanone.

Examples of the poor solvent include toluene, xylene, methanol, ethanol, isopropanol, propylene glycol monomethyl ether acetate, propylene glycol monomethyl ether, and water.

When the resin composition of the disclosure is a positive-type photosensitive resin composition, an exposed portion is removed with a developer.

Examples of a solution used as a positive-type developer include a tetramethylammonium hydroxide (TMAH) solution and a sodium carbonate solution.

At least one of the negative-type developer or the positive-type developer may contain a surfactant. The content of a surfactant with respect to 100 parts by mass of a developer is preferably from 0.01 parts by mass to 10 parts by mass, and more preferably from 0.1 parts by mass to 5 parts by mass.

The development time can be, for example, twice as long as the time required for a photosensitive resin film to be immersed in a developer until the resin film is completely dissolved.

The development time may be adjusted according to (A) a component in the resin composition of the disclosure, and is for example preferably from 10 seconds to 15 minutes, more preferably from 10 seconds to 5 minutes, and still more preferably, from the viewpoint of productivity, from 20 seconds to 5 minutes.

A patterned resin film after development may be washed with a rinse solution.

Distilled water, methanol, ethanol, isopropanol, toluene, xylene, propylene glycol monomethyl ether acetate, propylene glycol monomethyl ether, and the like may be used singly as a rinse solution or mixed as appropriate, or may be used in combination on a stepwise manner.

As an organic material constituting the insulating films 102 and 202 other than a cured product obtained by curing the resin composition of the disclosure, a photosensitive resin, a thermosetting non conductive film (NCF), or a thermosetting resin may be used. This organic material may be an underfill material. An organic material constituting the insulating films 102 and 202 may be a heat-resistant resin.

[Process (c) and Process (d)]

A process (c) is a process of polishing the first semiconductor substrate 100. In the process (c), as illustrated in (a) of FIG. 3, one side 101a which is the surface of the first semiconductor substrate 100 is polished using a CMP method in such a manner that each surface 103a of the terminal electrode 103 is at an equivalent position or slightly higher (protruding) than a surface 102a of the insulating film 102. In the process (c), for example, the first semiconductor substrate 100 may be polished by a CMP method under conditions that selectively deeply grind the terminal electrode 103, which are made of copper or the like. In the process (c), each surface 103a of the terminal electrode 103 may be polished by a CMP method in such a manner that the surface 103a of the terminal electrode 103 matches the surface 102a of the insulating film 102. The polishing method is not limited to a CMP method, and back grinding or the like may be employed.

When each surface 103a of the terminal electrode 103 is slightly higher than the surface 102a of the insulating film 102, the difference in height between each surface 103a and the surface 102a may be from 1 nm to 150 nm or from 1 nm to 15 nm.

A process (d) is a process of polishing the second semiconductor substrate 200. In the process (d), as illustrated in (a) of FIG. 3, one side 201a which is the surface of the second semiconductor substrate 200 is polished using a CMP method in such a manner that each surface 203a of the terminal electrode 203 is at an equivalent position or slightly higher (protruding) than a surface 202a of the insulating film 202. In the process (d), for example, the second semiconductor substrate 200 may be polished by a CMP method under conditions that selectively deeply grind the terminal electrode 203, which are made of copper or the like. In the process (d), each surface 203a of the terminal electrode 203 may be polished by a CMP method in such a manner that the surface 203a of the terminal electrode 203 matches the surface 202a of the insulating film 202. The polishing method is not limited to a CMP method, and back grinding or the like may be employed.

When each surface 203a of the terminal electrode 203 is slightly higher than the surface 202a of the insulating film 202, the difference in height between each surface 203a and the surface 202a may be from 1 nm to 50 nm or from 1 nm to 15 nm.

In the process (c) and the process (d), polishing may be performed in such a manner that the thickness of the insulating film 102 and the thickness of the insulating film 202 are the same, or for example, polishing may be performed in such a manner that the thickness of the insulating film 202 is greater than the thickness of the insulating film 102. On the other hand, polishing may be performed in such a manner that the thickness of the insulating film 202 is smaller than the thickness of the insulating film 102. When the thickness of the insulating film 202 is greater than the thickness of the insulating film 102, the insulating film 202 can encapsulate most of a foreign matter that adheres to a bonding interface during individualization of the second semiconductor substrate 200 or chip mounting, thereby further reducing bonding defects. On the other hand, when the thickness of the insulating film 202 is smaller than the thickness of the insulating film 102, the semiconductor chip 205 to be mounted, or the semiconductor device 1, can be made lower in height.

[Process (e)]

The process (e) is a process of individualizing the second semiconductor substrate 200 to obtain a plurality of semiconductor chips 205. In the process (e), as illustrated in (b) of FIG. 2, the second semiconductor substrate 200 is individualized into a plurality of semiconductor chips 205 by cutting means such as dicing. When dicing the second semiconductor substrate 200, the insulating film 202 may be coated with a protective material or the like and then individualized. By the process (e), the insulating film 202 of the second semiconductor substrate 200 is divided into insulating film portions 202b corresponding to the semiconductor chips 205. Examples of a dicing method for individualizing the second semiconductor substrate 200 include plasma dicing, stealth dicing, and laser dicing. A thin film of, for example, an organic film removable with water, TMAH, or the like, or a carbon film removable with plasma or the like may be provided as a surface protector of the second semiconductor substrate 200 during dicing.

[Process (f)]

The process (f) is a process for aligning the terminal electrodes 203 of the plurality of semiconductor chips 205 with the terminal electrodes 103 of the first semiconductor substrate 100. In the process (f), as illustrated in (c) of FIG. 2, the semiconductor chips 205 are aligned in such a manner that the terminal electrodes 203 of the semiconductor chips 205 are facing the corresponding plurality of terminal electrodes 103 of the first semiconductor substrate 100. An alignment mark or the like may be provided on the first semiconductor substrate 100 for such alignment.

[Process (g)]

The process (g) is a process of bonding the insulating film 102 of the first semiconductor substrate 100 and the insulating film portions 202b of the plurality of semiconductor chips 205 to each other. In the process (g), after removing an organic matter, a metal oxide, or the like adhered to the surface of each of the semiconductor chips 205, the semiconductor chips 205 are aligned with respect to the first semiconductor substrate 100 as illustrated in (c) of FIG. 2, and then, the insulating film portion 202b of each of the plurality of semiconductor chips 205 is bonded to the insulating film 102 of the first semiconductor substrate 100 as hybrid bonding (see (b) of FIG. 3). At this time, the insulating film portions of the plurality of semiconductor chips 205 and the insulating film 102 of the first semiconductor substrate 100 may be uniformly heated and then bonded. By bonding while heating, the insulating film 102 and the insulating film portion 202b expand more than the terminal electrodes 103 and 203 due to the difference between the thermal expansion coefficient of the insulating film 102 and the insulating film portion 202b and the thermal expansion coefficient of the terminal electrodes 103 and 203. Due to the thermal expansion caused by heating, the first semiconductor substrate 100 may be polished in the process (c) in such a manner that the height of the insulating film 102 is equal to or greater than the height of the terminal electrode 103, and the second semiconductor substrate 200 may be polished in the process (d) in such a manner that the height of the insulating film portion 202b is equal to or greater than the height of the terminal electrode 203. The temperature difference between the semiconductor chip 205 and the first semiconductor substrate 100 during bonding is, for example, preferably 10° C. or less. By heating and bonding at such a highly uniform temperature, the insulating film 102 and the insulating film portion 202b are bonded together to form an insulating bonding portion S1, and the plurality of semiconductor chips 205 are mechanically and firmly attached to the first semiconductor substrate 100. Since the bonding is performed by heating at a highly uniform temperature, misalignment or the like at the bonding points is unlikely to occur, and bonding can be performed with high precision. At this stage of attachment, the terminal electrode 103 of the first semiconductor substrate 100 and the terminal electrode 203 of the semiconductor chip 205 are separated from each other, and are not connected (but are aligned). The semiconductor chip 205 may be attached to the first semiconductor substrate 100 by another bonding method, such as room temperature bonding.

The thickness of the organic insulating film, which is the insulating bonding portion where the insulating film 102 and the insulating film portion 202b are bonded, is not particularly limited, and may be, for example, 0.1 μm or more, or from the viewpoint of controlling influence of a foreign matter or device design, 1 μm to 20 μm, and is preferably from 1 μm to 5 μm.

[Process (h)]

The process (h) is a process of bonding the terminal electrodes 103 of the first semiconductor substrate 100 to the terminal electrodes 203 of the plurality of semiconductor chips 205. In the process (h), as illustrated in (d) of FIG. 2, after the bonding of the process (g) is completed, heat H, pressure, or both are applied to bond the terminal electrodes 103 of the first semiconductor substrate 100 and the terminal electrodes 203 of the plurality of semiconductor chips 205 for hybrid bonding (see (c) of FIG. 3). When the terminal electrodes 103 and 203 are composed of copper, the annealing temperature in the process (g) is preferably from 150° C. to 400° C., and more preferably from 200° C. to 300° C. This bonding process results in an electrode bonding portion S2 where the terminal electrode 103 and the corresponding terminal electrode 203 are bonded together, and the terminal electrode 103 and the terminal electrode 203 are mechanically and electrically firmly bonded. The electrode bonding of the process (h) may be performed after the bonding of the process (g) or simultaneously with the bonding of the process (g).

As described above, the plurality of semiconductor chips 205 are electrically and mechanically placed at a predetermined position on the first semiconductor substrate 100 with high precision. At a stage of semi-finished products illustrated in (d) of FIG. 2, for example, a product reliability test (connection test or the like) may be conducted, and only good products may be used in a subsequent process. A method for producing one example of a semiconductor device using such a semi-finished product is then described with reference to FIG. 4.

[Process (i)]

The process (i) is a process of forming the plurality of pillars 300 on the connecting surface 100a of the first semiconductor substrate 100 and between the plurality of semiconductor chips 205. In the process (i), as illustrated in (a) of FIG. 4, multiple pillars 300 made of copper, for example, are formed between the plurality of semiconductor chips 205. The pillars 300 can be formed from copper plating, conductor paste, copper pins, or the like. The pillar 300 is formed in such a manner that one end is connected to a terminal electrode of the first semiconductor substrate 100 that is not connected to the terminal electrode 203 of the semiconductor chip 205, and the other end extends upward. The pillar 300 is, for example, from 10 μm to 100 μm in diameter and from 10 μm to 1000 μm in height. For example, from 1 to 10,000 pillars 300 may be provided between a pair of semiconductor chips 205.

[Process (j)]

The process (j) is a process of molding the resin 301 on the connecting surface 100a of the first semiconductor substrate 100 in such a manner that the plurality of semiconductor chips 205 and the plurality of pillars 300 are covered. In the process (j), as illustrated in (b) of FIG. 4, an epoxy resin or the like is molded and covers the plurality of semiconductor chips 205 and the plurality of pillars 300 entirely. Examples of the molding method include compression molding, transfer molding, and laminating a film epoxy film. With this resin molding, the space between the plurality of pillars 300 and between the pillar 300 and the semiconductor chip 205 is filled with the resin 301.

This forms a resin-filled semi-finished product M1. A curing process may be performed after a epoxy resin or the like is molded. When the process (i) and the process (j) are performed almost at the same time, in other words, when the pillar 300 is also formed at the same time as the resin molding, the pillar may be formed using imprinting, which is a micro-transfer process, and conductive paste or electrolytic plating.

[Process (k)]

The process (k) is a process to obtain a semi-finished product M2 by grinding and thinning the semi-finished product M1, which is composed of the resin 301, the plurality of pillars 300, and the plurality of semiconductor chips 205 molded in the process (j), from the resin 301 side. In the process (k), as illustrated in (c) of FIG. 4, the resin-molded first semiconductor substrate 100 and the like are thinned by polishing the upper side of the semi-finished product M1 with a grinder or the like, to obtain the semi-finished product M2. By polishing in the process (k), the thickness of the semiconductor chip 205, the pillar 300, and the resin 301 is thinned to a few 10 for example, and the semiconductor chip 205 becomes a shape corresponding to the second semiconductor chip 20, and the pillar 300 and the resin 301 become a shape corresponding to the pillar portion 30.

[Process (l)]

The process (l) is a process of forming the wiring layer 400 corresponding to the rewiring layer 40 on the semi-finished product M2 thinned in the process (k). In the process (l), as illustrated in (d) of FIG. 4, a rewiring pattern is formed on the second semiconductor chip 20 and the pillar portion 30 of the ground semi-finished product M2 using polyimide, copper wiring, or the like. This forms a semi-finished product M3 having a wiring structure with a wider terminal pitch of the second semiconductor chip 20 and the pillar portion 30.

[Process (m) and Process (n)]

The process (m) is a process of cutting the semi-finished product M3, in which the wiring layer 400 is formed in the process (l), along the cutting line A to form the semiconductor devices 1. In the process (m), as illustrated in (d) of FIG. 4, a semiconductor device substrate is cut along the cutting line A by dicing or the like to form the semiconductor device 1. Then, in the process (n), the semiconductor devices 1a individualized in the process (m) are inverted and placed on the substrate 50 and the circuit board 60 to obtain the plurality of semiconductor devices 1 illustrated in FIG. 1.

According to the method for producing a semiconductor device described above, the insulating film 102 of the first semiconductor substrate 100 and the insulating film 202 of the second semiconductor substrate 200 are cured products obtained by curing the resin composition of the disclosure. Since a cured product obtained by curing the resin composition of the disclosure has a lower modulus of elasticity than an inorganic material such as silicon dioxide, by using the resin composition in preparing an insulating film for hybrid bonding, even when a foreign matter generated by dicing when the second semiconductor substrate 200 is individualized into the semiconductor chips 205 adheres to the insulating film, the insulating film around the foreign matter is easily deformed and the foreign matter can be contained in the insulating film without creating a large void in the insulating film. In other words, an insulating film can reduce influence of a foreign matter. Therefore, according to the production method of the embodiment, bonding defects can be reduced while micro-bonding the first semiconductor substrate 100 and the semiconductor chip 205. When the resin composition of the disclosure includes a material with a low modulus of elasticity or has a resin composition with high toughness, damage of the semiconductor device 1 produced by the above-described production method can be more surely reduced.

Although one embodiment of the method for producing a semiconductor device of the disclosure has been described in detail above, the invention is not limited to the above-described embodiment. For example, in the above-described embodiment, in the process illustrated in FIG. 4, after the process (i) of forming pillar 300, the processes (j) of molding the resin 301 and the process (k) of grinding and thinning the resin 301 and the like are performed in sequence, but the process (j) of molding the resin 301 onto the connecting surface of the first semiconductor substrate 100 may be performed first, followed by the process (k) of grinding and thinning the resin 301 to a predetermined thickness, and then the process (i) of forming the pillar 300 may be performed. In this case, operation such as shaving the pillar 300 can be reduced, and the material cost can be reduced because no portion of the pillar 300 needs to be shaved.

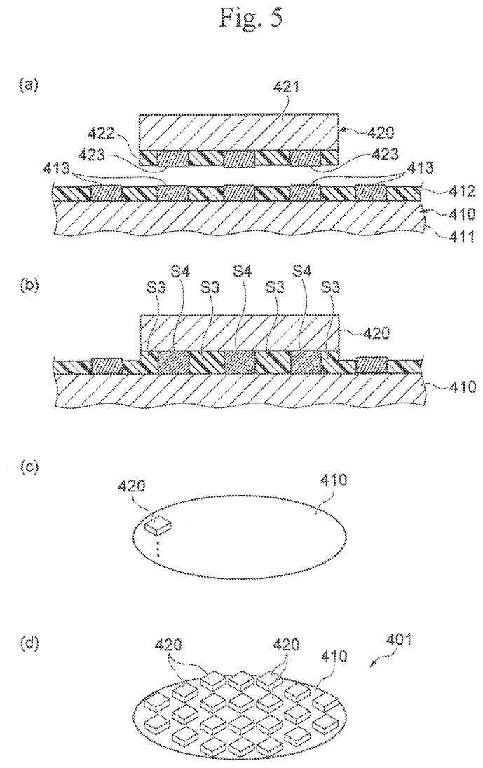

In the above-described embodiment, an example of bonding in C2C is described, but the invention may be applied to bonding in Chip-to-Wafer (C2W) illustrated in FIG. 5. In C2W, a semiconductor wafer 410 (first semiconductor substrate) including a substrate body 411 (first substrate body), an insulating film 412 (first insulating film), and a plurality of terminal electrodes 413 (first electrodes) provided on one side of the substrate body 411 is prepared, and a semiconductor substrate (second semiconductor substrate) before individualization of a plurality of semiconductor chips 420 including a substrate body 421 (second substrate body), and an insulating film portion 422 (second insulating film) and a plurality of terminal electrodes 423 (second electrodes) that are provided on one side of the substrate body 421, is also prepared. Then, one side of the semiconductor wafer 410 and one side of the second semiconductor substrate before individualization into semiconductor chips 420 are polished by a CMP method or the like, as in the above-described process (c) and process (d). Then, an individualization process similar to the process (e) is performed on the second semiconductor substrate to obtain the plurality of semiconductor chips 420.

Then, as illustrated in (a) of FIG. 5, the terminal electrode 423 of the semiconductor chip 420 is aligned with the terminal electrode 413 of the semiconductor wafer 410 (process (f)). Then, the insulating film 412 of the semiconductor wafer 410 and the insulating film portion 422 of the semiconductor chip 420 are attached to each other (process (g)), and the terminal electrode 413 of the semiconductor wafer 410 and the terminal electrode 423 of the semiconductor chip 420 are bonded (process (h)) to obtain a semi-finished product illustrated in (b) of FIG. 5. This results in an insulated bonding portion S3 where the insulating film 412 and the insulating film portion 422 are bonded together, and the semiconductor chip 420 is mechanically and rigidly attached to the semiconductor wafer 410 with high precision. The terminal electrode 413 and the corresponding terminal electrode 423 are bonded together to form an electrode bonding portion S4, and the terminal electrode 413 and the terminal electrode 423 are mechanically and electrically firmly bonded together.

Then, as illustrated in (c) and (d) of FIG. 5, a semiconductor device 401 is obtained by bonding a plurality of semiconductor chips 420 to a semiconductor wafer, semiconductor wafer 410, in a similar manner. The plurality of semiconductor chips 420 may be bonded to the semiconductor wafer 410 one by one by hybrid bonding, or may be bonded collectively to the semiconductor wafer 410 by hybrid bonding.

In such a method for producing the semiconductor device 401, as in the method for producing the semiconductor device 1 described above, at least one of the insulating film 412 of the semiconductor wafer 410 or the insulating film portion 422 of the semiconductor chip 420 is an insulating film that is a cured product obtained by curing the resin composition of the disclosure. Therefore, even when a foreign matter generated by dicing during individualization into the semiconductor chips 420 adheres to an insulating film, the insulating film around the foreign matter is easily deformed and the foreign matter can be contained in the insulating film without creating a large void in the insulating film. In other words, the insulating film can reduce influence of a foreign matter. Therefore, in the above-described production method for C2W, as with C2C, bonding defects can be reduced while micro-bonding of the semiconductor wafer 410 and the semiconductor chip 420 is performed.

Furthermore, in the above-described method for producing a semiconductor device, an inorganic material may be included in part of the insulating film 102 of the semiconductor substrate 110 and the insulating film 202 of the semiconductor chip 205, to an extent that an effect of the invention is achieved.

### EXAMPLES

Hereinafter, the disclosure will be described in more detail based on Examples and Comparative Examples. The disclosure is not limited to the following Examples.

### Synthesis Example 1 (Synthesis of A1)

7.07 g of 3,3′,4,4′-diphenyl ether tetracarboxylic dianhydride (ODPA) and 4.12 g of 2,2′-dimethylbiphenyl-4,4′-diamine (DMAP) were dissolved in 30 g of N-methyl-2-pyrrolidone (NMP). The resulting solution was stirred at 30° C. for 4 hours and then overnight at room temperature to obtain polyamide acid. Then 9.45 g of trifluoroacetic anhydride was added at room temperature, followed by addition of 7.08 g of 2-hydroxyethyl methacrylate (HEMA) and stirring at 45° C. for 10 hours. The reaction liquid was added dropwise to distilled water, and the precipitate was filtered off, collected, and dried under reduced pressure to obtain a polyimide precursor A1.

The weight average molecular weight of A1 was determined using gel permeation chromatography (GPC) by standard polystyrene conversion. The weight average molecular weight of A1 was 20,000. Specifically, a solution of 0.5 mg of A1 dissolved in 1 mL of solvent [tetrahydrofuran (THF)/dimethylformamide (DMF)=1/1 (volume ratio)] was used, and the measurement was performed under the following conditions.

### (Measurement Conditions)

Measure apparatus: SHIMADZU CORPORATION SPD-M20A

### Pump: SHIMADZU CORPORATION LC-20AD

Column oven: SHIMADZU CORPORATION: CTO-20A
Measurement conditions: column Gelpack GL-S300MDT-5×2
Eluent: THF/DMF=1/1 (volume ratio)

LiBr (0.03 mol/L), H₃PO₄ (0.06 mol/L)

Flow velocity: 1.0 mL/min, detector: UV270 nm, column temperature: 40° C.

Standard polystyrene: TSKgel standard Polystyrene Type F-1, F-4, F-20, F-80, A-2500 manufactured by Tosoh Corporation were used to create a calibration curve.

<Esterification Rate>

The esterification ratio of A1 (ratio of ester groups formed by reacting with HEMA to the sum of ester groups formed by reacting with HEMA and unreacted carboxy groups with HEMA) was calculated by performing NMR measurements under the following conditions. The esterification ratio was 80% by mole, and the ratio of unreacted carboxy groups was 20% by mole.

### (Measurement Conditions)

Measurement apparatus: Bruker Biospin K.K. AV400M
Magnetic field strength: 400 MHz
Reference substance: Tetramethylsilane (TMS)
Solvent: Dimethyl sulfoxide (DMSO)

### Synthesis Example 2 (Synthesis of A2)

A polyimide precursor A2 was obtained by the same method as in Synthesis Example 1, except that NMP was changed to 3-methoxy-N,N-dimethylpropanamide. The weight average molecular weight of A2 was 22,000.

The esterification ratio of A2 was calculated by performing NMR measurements under the above-described conditions. The esterification ratio was 70% by mole, and the ratio of unreacted carboxy groups was 30% by mole.

### Synthesis Example 3 (Synthesis of A3)

A polyimide precursor A3 was obtained by the same operation except that 2,2′-dimethylbiphenyl-4,4′-diamine (DMAP) of Synthesis Example 1 was changed to 3.6 g of 4.4′-diaminodiphenyl ether and 0.2 g of m-phenylenediamine. The weight average molecular weight of A3 was 25,000.

The esterification ratio of A3 was calculated by performing NMR measurements under the above-described conditions. The esterification ratio was 72% by mole, and the ratio of unreacted carboxy groups was 28% by mole.

### Synthesis Example 4 (Synthesis of A4)

A polyimide precursor A4 was obtained by the same method as in Synthesis Example 3, except that NMP was changed to 3-methoxy-N,N-dimethylpropanamide. The weight average molecular weight of A4 was 22,000.

The esterification ratio of A4 was calculated by performing NMR measurements under the above-described conditions. The esterification ratio was 70% by mole, and the ratio of unreacted carboxy groups was 30% by mole.

### Synthesis Example 5 (Synthesis of A5)

61.0 g of 3,3′,4,4′-diphenyl ether tetracarboxylic dianhydride (ODPA) and 52.0 g of 1,3-bis(3-aminophenoxy)benzene were dissolved in 200 g of 3-methoxy-N,N-dimethylpropanamide. The resulting solution was stirred at 30° C. for 2 hours and then overnight at room temperature to obtain polyamide acid. 80 g of trifluoroacetic anhydride was added thereto at room temperature and stirred for a predetermined time, and then 7.2 g of 2-hydroxyethyl methacrylate (HEMA) was added, and the mixture was stirred at 45° C. for 10 hours. The reaction liquid was added dropwise to distilled water, the precipitate was filtered off and collected, and dried under reduced pressure to obtain a polyimide precursor A5. The weight average molecular weight of A5 was 25,000.

### Synthesis Example 6 (Synthesis of A6)

In a reaction container, 155 g of ODPA and 131.2 g of HEMA were dissolved in 400 mL of γ-butyrolactone and stirred at room temperature, then 81 g of pyridine was added while stirring to obtain a reaction mixture. After the end of exothermic reaction, the reaction mixture was cooled to room temperature and allowed to stand for 15 hours.

Next, a solution of 206.3 g of dicyclohexylcarbodiimide (DCC) dissolved in 180 mL of γ-butyrolactone was added to the reaction mixture over 40 minutes with stirring under ice cold conditions. Next, a suspension of 93 g of 4,4′-diaminodiphenyl ether in 350 mL of γ-butyrolactone was added to the reaction mixture over 60 minutes with stirring. After stirring the reaction mixture for 2 hours at room temperature, 30 mL of ethyl alcohol was added and stirred for 1 hour, then 400 mL of γ-butyrolactone was added to the reaction mixture. The precipitate formed in the reaction mixture was removed by filtration to obtain a reaction liquid.

The obtained reaction liquid was added to 3 liters of ethyl alcohol to produce a precipitate composed of a crude polymer. The crude polymer produced was filtered out and dissolved in 1 liter of tetrahydrofuran to obtain a crude polymer solution. The resulting crude polymer solution was added dropwise to water to precipitate a polymer, and the resulting precipitate was filtered off and vacuum-dried to obtain a polyimide precursor A6, which is a powdery polymer. The weight average molecular weight of A6 was 24,000.

The esterification ratio of A6 was calculated by performing NMR measurements under the above-described conditions. The esterification ratio was 100% by mole.

### Synthesis Example 7 (Synthesis of A7)

A polyimide precursor A7 was obtained by the same method as in Synthesis Example 6, except that 155 g of ODPA was changed to 147 g of 3,3′-4.4′-biphenyltetracarboxylic dianhydride. The weight average molecular weight of A7 was 28,000.

The esterification ratio of A7 was calculated by performing NMR measurements under the above-described conditions. The esterification ratio was nearly 100% by mole.

In Comparative Example 1 below, the following polymer components A8 and A9 were used as polymers other than polyimide precursors.

A8: Cresol-formaldehyde resin (manufactured by ASAHI YUKIZAI CORPORATION), weight average molecular weight 12,000
A9: Acrylic acid polymerization (butyl acrylate/acrylic acid/4-hydroxybutyl acrylate) (Synthesis Example 10 (Synthesis of A10))

18.7 g of ODPA and 6.54 g of PMDA, dried in a dryer at 160° C. for 24 hours, were added to 400 g of 3-methoxy-N,N-dimethylpropanamide. To a solution obtained by stirring, a suspension of 29.1 g of 1,3-bis(3-aminophenoxy)benzene suspended in 100 g of 3-methoxy-N,N-dimethylpropanamide was added dropwise to prepare a mixed liquid. After stirring the mixed liquid at 30° C. for 4 hours, 1.5 g of diazabicycloundecene was added to the mixed liquid, and the mixture was stirred at 150° C. for 2 hours. The mixed liquid was added dropwise to distilled water, and the precipitate was filtered off, collected, and dried under reduced pressure to obtain a polyimide resin A10. The weight average molecular weight of A10 was 10,000.

### Examples 1 to 8, Comparative Example 1

### (Preparation of Resin Composition)

Resin compositions of Examples 1 to 8 and Comparative Example 1 were prepared as follows with the ingredients and blended amounts shown in Table 1. The unit for the blended amounts of components in Table 1 is parts by mass. A blank column in Table 1 means that the relevant component has not been blended. In each of Examples and Comparative Examples, the mixture of each component was kneaded overnight at room temperature in a general solvent-resistant container, and then pressure filtered using a 0.2 μm pore filter. The resin compositions obtained were subjected to the following evaluations.

Components in Table 1 are as follows.

Polymer Components
A1 to A10 described above

(B) Component (Solvent)
B1: 3-Methoxy-N,N-dimethyl propionamide
B2: N-Methyl-2-pyrrolidone
B3: Methyl lactate
B4: γ-Butyrolactone

(D) Component (Polymerizable Monomer)
D1: Triethylene glycol dimethacrylate (TEGDMA)
D2: 1,6-Hexanediol diglycidyl ether
D3: Triglycidyl-p-aminophenol
D4: Hexakis(methoxymethyl)melamine (Cymel)
D5: Urea/alkyl(C1-5)aldehyde/alkyl(C2-10)poly(2-4)aldehyde/alkyl(C1-12)monoalcohol polycondensation product (MX270)
D6: 4,4′-(1,1,1,3,3,3-hexafluoropropane-2,2-diyl)bis[2,6-bis(hydroxymethyl)phenol]

Rust Inhibitor
Rust inhibitor 1: Benzotriazole
Rust inhibitor 2: 5-Amino-1H-tetrazole
Rust inhibitor 3: 1-H-Tetrazole

Adhesion Aid
Adhesion aid 1: 50% methanol solution of 3-ureidopropyltriethoxysilane
Adhesion aid 2: 60% ethanol solution of N,N′-bis(2-hydroxyethyl)-3-aminopropyltriethoxysilane (SIB 1140)

(C) Component (Photoinitiator)
C1: 1-Phenyl-1,2-propane dione-2-(o-ethoxycarbonyl)oxime
C2: Ethanone,1-[9-ethyl-6-(2-methylbenzoyl)-9H-carbazol-3-yl]-, 1-(O-acetyloxime)
C3: 4,4′-bis(diethylamino)benzophenone
C4: Irgacure OXE01
C5: Compound represented by the following Formula (Y)

(E) Component (Thermal Polymerization Initiator)
E1: Bis(1-phenyl-1-methylethyl)peroxide

(F) Component (Polymerization Inhibitor)
F1: N,N′-hexane-1,6-diyl bis[3-(3,5-di-tert-butyl-4-hydroxyphenyl)propionamide]

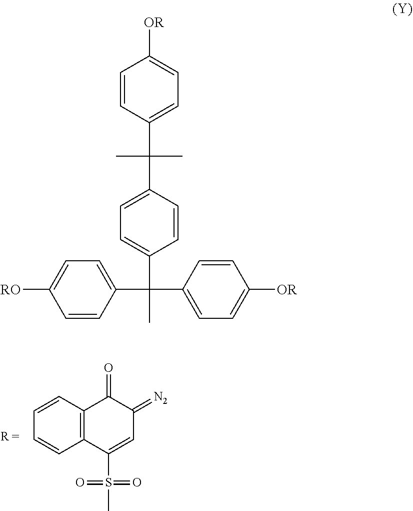

(Measurement of Storage Modulus of Cured Film and the Like)

Photosensitive resin compositions of Examples 1 to 4, 7, 8 and Comparative Example 1 were used to form cured films as follows, and then the storage modulus was measured. The photosensitive resin composition was spin-coated onto a Si substrate, and then heated and dried on a hot plate at the temperature (° C.) and time in Table 1 (s in Table 1) in the drying conditions during film formation to form a photosensitive resin film that is approximately 10 μm after curing.

The resulting photosensitive resin films were exposed with a mask aligner MA-8 (Zuse Microtec) using broadband (BB) exposure at the exposure doses shown in Table 1. The exposed resin film was developed by cyclopentanone (corresponding to Dev1 in Table 1) for Examples 1 to 4, 7 and 8 and by 2.38% TMAH solution (corresponding to Dev2 in Table 1) for Comparative Example 1 for the times shown in Table 1 using Coater Developer ACT8 (manufactured by Tokyo Electron Limited) to obtain a 10 mm wide strip patterned resin film.

The obtained patterned resin film was cured under a nitrogen atmosphere using a vertical diffusion furnace μ-TF at the temperature and time shown in Table 1 to obtain a pattern cured product with a thickness of 10

The resulting pattern cured product was immersed in a 4.9% by mass hydrofluoric acid solution, and the 10 mm wide pattern cured product was peeled off from the Si substrate.

The storage modulus and loss modulus of the pattern cured product peeled off from the Si substrate were measured at a test frequency of 1 Hz, a temperature increase rate of 5° C./min, in a measurement mode: tensile, under N₂ atmosphere, at a measurement range of from −50° C. to 400° C., with a distance of 10 mm between chucks, and with a sample width of 2.0 mm using the RSA-G2 manufactured by TA Instruments.

The loss tangent was determined from the obtained storage modulus and loss modulus, and the peak of the loss tangent was set as Tg (glass transition temperature). In addition, G2/G1 was obtained from the storage modulus at a temperature 100° C. lower than Tg (G1 in Table 2) and the storage modulus at a temperature 100° C. higher than Tg (G2 in Table 2). The results are shown in Table 2.

G2/G1 in Table 2 is preferably 0.3 or less, more preferably 0.1 or less, and still more preferably 0.05 or less.

(Preparation of Cured Film with Chip)

The resin compositions of Examples 1 to 8 and Comparative Example 1 were spin-coated onto an 8-inch Si wafer using a spin coater, followed by a drying process to form a resin film. When the resin composition is a photosensitive resin composition, a mask capable of producing a circular resin film with a diameter of 180 mm was placed on the obtained resin film, and light with a wavelength of 365 nm was irradiated at a predetermined exposure dose. A patterned resin film was then prepared by removing 10 mm from the outer edge of the resin film on the Si wafer by developing the film for a predetermined time using cyclopentanone or 2.38% TMAH. When the resin composition was not a photosensitive resin composition, about 10 mm from the wafer periphery was removed by edge rinsing the edge of the resin film after spin coating with cyclopentanone to produce a circular resin film with a diameter of about 180 mm. The resin film was heated in a clean oven under a nitrogen atmosphere at the temperatures shown in Table 3 for a specified time to obtain a cured film with a thickness of 2 μm to 8 μm after curing.

The obtained cured film was polished by a CMP process to obtain a polished cured film with a surface roughness Ra of from 0.5 nm to 3 nm within 10 μm 2 as measured using an AFM (atomic force microscope). After scrubbing the polished cured film with a common cleaning liquid, a part of the cleaned polished cured film was cut into 5 mm square pieces by a blade dicer (DISCO DFD-6362) to obtain resin-impregnated chips. The resulting chip with resin was bonded to the polished cured film by a flip chip bonder for 15 seconds at the specified pressure and bonding temperatures shown in Table 3 to produce a cured film with a chip. The evaluation described below was conducted for each resin composition on each of the five chips that were bonded to the polished cured film.

### Comparative Example 2

(Preparation of SiO₂ Wafer with Chip)

A SiO₂ wafer prepared by a thermal oxidation method was prepared, and a polished SiO₂ wafer was prepared by the method described above for preparing a sample for adhesion evaluation. A part of the prepared polished SiO₂ wafers was cut into pieces and SiO₂ chips were prepared. The obtained SiO₂ chip was bonded to a polished SiO₂ wafer in the same way as in the preparation of the cured film with a chip described above, and a SiO₂ wafer with a chip was prepared. In the SiO₂ wafer with a chip, five SiO₂ chips were bonded to a polished SiO₂ wafer,

The obtained cured film with a chip and SiO₂ wafer with a chip were observed using scanning acoustic tomography (SAT) for the presence of a void indicating an adhesion defect between a resin interface or between the resin and the substrate. The evaluation criteria for a void are as follows. The results are shown in Table 3. An evaluation of “A” indicates that voids were reduced, and the evaluation is considered favorable.

—Void Evaluation Criteria—

A: Two or fewer chips with observed voids out of five chips.
B: More than two chips with observed voids out of five chips.
C: One or more chips peeled off during SAT measurement.

The obtained cured film with a chip and SiO₂ wafer with a chip were measured for adhesion strength between the SiO₂ wafer and the SiO₂ chip or the cured films, which are the insulating layers, using a shear tester. The adhesive strength was evaluated using the following criteria. The results are shown in Table 3.

—Adhesion Evaluation Criteria—

A: The average of the shear strength of five chips was 1 Mpa or higher.
B: The average of the shear strength of five chips was 1 Mpa or less.
C: The adhesive strength is too low to measure.

When the adhesive strength was 1 MPa or higher, the processes after the preparation of the cured film with a chip were able to be carried out without any problems.

(Study of Thermal Compression Bonding)

When hybrid bonding a copper terminal together with an insulating layer, bonding is generally performed by applying pressure at a temperature of from 200° C. to 400° C. due to reliability issues of the copper terminal. When the insulating layer is a cured film of an insulating resin, a void or the like may occur due to volatile matter generated by a thermal decomposition of the insulating resin during bonding. Therefore, the above-described cured film with a chip was evaluated for the occurrence of a void or the like by further high-temperature thermal compression bonding, and whether the bonding strength is reduced or not.

(Evaluation after Thermal Compression Bonding)

A carbon sheet for absorbing steps was placed over the above-described cured film with a chip, and bonding was performed using a crimping machine (manufactured by EVG) for 4 hours at 300° C. under specified vacuum conditions, applying a load of 7,200 N to an 8-inch pressurized area. The presence of voids and the adhesive strength between cured films were then evaluated in the same manner as described above. The evaluation criteria for the presence of voids and adhesive strength were as follows. The results are shown in Table 3.

—Evaluation Criteria for Voids after Thermal Compression Bonding—

A: Two or fewer chips with observed voids out of five chips.
B: More than two chips with observed voids out of five chips.
C: One or more chips peeled off during SAT measurement.

—Evaluation Criteria for Adhesive Strength after Thermal Compression Bonding

A+: Failure mode of at least three chips out of five chips is cohesive failure of the Si portion.
A: The average shear strength of five chips is 5 MPa or higher.
B: The average shear strength of five chips is less than 5 MPa.
C: The bonding strength is too low to measure.

TABLE 1

| | | Exam- | Exam- | Exam- | Exam- | Exam- | Exam- | Exam- | Exam- | Comparative |
|---|---|---|---|---|---|---|---|---|---|---|
| | | ple 1 | ple 2 | ple 3 | ple 4 | ple 5 | ple 6 | ple 7 | ple 8 | Example 1 |
| (A) | A1 | 100 | | | | | | | | |
| Component | A2 | | 100 | | | | | | | |
| Polymer | A3 | | | 100 | | | | | | |
| | A4 | | | | 100 | 100 | 100 | | | |
| | A5 | | | | | | | 100 | | |
| | A6 | | | | | | | | 25 | |
| | A7 | | | | | | | | 100 | |
| | A8 | | | | | | | | | 100 |
| | A9 | | | | | | | | | 25 |
| | A10 | | | | | | 30 | | | |
| (B) | B1 | 150 | 150 | | 170 | 170 | 250 | | | |
| Component | B2 | | | 150 | | | | 170 | | |
| Solvent | B3 | | | | | | | | 80 | 200 |
| | B4 | | | | | | | | 20 | |
| (D) | D1 | 15 | 15 | 15 | 15 | 15 | 10 | 15 | | |
| Component | D2 | | | | | | | | | 25 |
| Polymerizable | D3 | | | | | | | | | 20 |
| monomer | D4 | | | | | | | | | 1 |
| | D5 | | | | | | | | | |
| | D6 | | | | | | | | | |
| Rust inhibitor | 1 | 3 | 3 | 3 | 3 | 3 | 3 | 3 | | |
| | 2 | | | | | | | | 2 | 2 |
| | 3 | | | | | | | | | |
| Adhesion aid | 1 | 5 | 5 | 2 | 2 | 2 | 2 | 2 | | |
| | 2 | | | | | | | | | |
| (C) | C1 | 5 | 5 | | | | | | | |
| Component | C2 | | | 2 | 2 | | | 2 | | |
| Photoinitiator | C3 | 1 | 1 | | | | | | | |
| | C4 | | | | | | | | 3 | |
| | C5 | | | | | | | | | 10 |
| (E) | E1 | | | | | 2 | 2 | | | |
| Component | | | | | | | | | | |
| Thermal | | | | | | | | | | |
| polymerization | | | | | | | | | | |
| initiator | | | | | | | | | | |
| (F) | G1 | | | 3 | 3 | | | 3 | | |
| Component | | | | | | | | | | |
| Polymerization | | | | | | | | | | |
| inhibitor | | | | | | | | | | |
| Drying | ° C./s | 100/240 | 100/240 | 100/240 | 100/240 | 100/240 | 100/240 | 100/240 | 100/240 | 120/180 |
| conditions | | | | | | | | | | |
| during film | | | | | | | | | | |
| formation | | | | | | | | | | |
| Development | Solvent/development | Dev1/20 | Dev1/20 | Dev1/20 | Dev1/20 | — | — | Dev1/20 | Dev1/20 | Dev2/100 |
| conditions | time (secs) | | | | | | | | | |
| Exposure dose | mJ/cm² | 300 | 300 | 300 | 300 | — | — | 300 | 300 | 600 |
| Curing | Curing temperature | 375° C. | 300, 375° C. | 375° C. | 300, 375° C. | 375° C. | 350° C. | 230, 300, | 250° C. | 250° C. |
| Conditions | | | | | | | | 350° C. | | |
| | Curing time | 2 | 2 | 2 | 2 | 2 | 2 | 2 | 2 | 1 |
| | (time) | | | | | | | | | |

TABLE 2

| | | | Measurement | | Measurement | |
|---|---|---|---|---|---|---|
| | Curing | Storage | temperature | Storage | temperature | |
| | temperature | modulus G1 | of G1 | modulus G2 | of G2 | |
| | (° C.) | (GPa) | (° C.) | (GPa) | (° C.) | G2/G1 |
| Example 1 | 375 | 1.89 | 225 | 0.08 | 425 | 0.042 |
| Example 2 | 375 | 1.9 | 230 | 0.09 | 430 | 0.047 |
| Example 3 | 375 | 1.96 | 180 | 0.0099 | 380 | 0.005 |
| Example 4 | 375 | 1.85 | 175 | 0.0096 | 370 | 0.005 |
| Example 5 | 375 | 2.0 | 150 | 0.012 | 350 | 0.006 |
| Example 6 | 350 | 1.3 | 150 | 0.043 | 350 | 0.033 |
| Example 7 | 230 | 1.9 | 50 | 0.012 | 250 | 0.006 |
| Example 8 | 250 | 2.1 | 140 | 0.0098 | 340 | 0.005 |
| Comparative | 250 | 1.6 | 100 | 0.04 | 300 | 0.025 |
| Example 1 | | | | | | |

TABLE 3

| | | Evaluation of cured film with | | | | | |
|---|---|---|---|---|---|---|---|
| | | chip and SiO₂ wafer with chip | | | | Evaluation after thermal | |
| | Curing | | Bonding | | | compression bonding | |
| | temperature | Presence | temperature | Void | Adhesion | Void | |
| | (° C.) | of CMP | (° C.) | evaluation | strength | evaluation | Adhesion |
| Example 1 | 375 | Yes | 350 | A | A | A | A+ |
| Example 2 | 300 | Yes | 250 | A | A | A | A+ |
| | 375 | Yes | 250 | A | A | A | A+ |
| | 375 | Yes | 300 | A | A | A | A+ |
| | 375 | Yes | 350 | A | A | A | A+ |
| Example 3 | 375 | Yes | 350 | A | A | A | A+ |
| Example 4 | 300 | Yes | 250 | A | A | A | A+ |
| | 375 | Yes | 250 | A | A | A | A+ |
| | 375 | Yes | 300 | A | A | A | A+ |
| | 375 | Yes | 350 | A | A | A | A+ |
| | 375 | None | 350 | A | B | A | A+ |
| Example 5 | 375 | Yes | 350 | A | A | A | A+ |
| Example 6 | 350 | Yes | 300 | A | A | A | A+ |
| Example 7 | 250 | Yes | 250 | A | A | A | A+ |
| | 300 | Yes | 300 | A | A | A | A+ |
| | 350 | None | 350 | A | A | A | A+ |
| Example 8 | 250 | Yes | 250 | A | B | A | A+ |
| Comparative | 250 | Yes | 200 | B | B | — | — |
| Example 1 | | | | | | | |
| Comparative | — | Yes | 25 | C | C | — | — |
| Example 2 | — | Yes | 50 | C | C | — | — |
| | — | Yes | 150 | C | C | — | — |
| | — | Yes | 350 | C | C | — | — |
| | — | None | 350 | C | C | — | — |

As shown in Table 3, generation of voids in the cured film with a chip was suitably reduced in Examples 1 to 8 compared to Comparative Example 1.

On the other hand, in Comparative Example 2, peeling off of a chip was observed on a SiO₂ wafer with a chip due to influence of voids.

The disclosure of PCT/JP2020/037322, filed Sep. 30, 2020, is incorporated herein by reference in its entirety.

All references, patent applications, and technical standards described herein are incorporated by reference herein to the same extent that individual references, patent applications, and technical standards are specifically and individually noted as being incorporated by reference.

### REFERENCE SIGNS LIST

1, 1a, 401 . . . Semiconductor device, 10 . . . First semiconductor chip, 20 . . . Second semiconductor chip, 30 . . . Pillar portion, 40 . . . Rewiring layer, 50 . . . Substrate, 60 . . . Circuit board, 61 . . . Terminal electrode, 100 . . . First semiconductor substrate, 101 . . . First substrate body, 101a . . . One side, 102 . . . Insulating film (first insulating film), 103 . . . Terminal electrode (first electrode), 103a . . . Surface, 200 . . . Second semiconductor substrate, 201 . . . Second substrate body, 201a . . . One side, 202 . . . Insulating film (second insulating film), 203 . . . Terminal electrode (second electrode), 203a . . . Surface, 205 . . . Semiconductor chip, 300 . . . Pillar, 301 . . . Resin, 410 . . . Semiconductor wafer (first semiconductor substrate), 411 . . . Substrate body (first substrate body), 412 . . . Insulating film (first insulating film), 413 . . . Terminal electrode (first electrode), 420 . . . Semiconductor chip (second semiconductor substrate), 421 . . . Substrate body (second substrate body), 422 . . . Insulating film portion (second insulating film), 423 . . . Terminal electrode (second electrode), A . . . Cutting line, H . . . Heat, M1 to M3 . . . Semi-finished product, S1 . . . Insulated bonding portion, S2 . . . Electrode bonding portion, S3 . . . Insulated bonding portion, S4 . . . Electrode bonding portion.

1. A resin composition that contains (A) at least one of a polyimide precursor, which is at least one resin selected from the group consisting of a polyamide acid, a polyamide acid ester, a polyamide acid salt, and a polyamide acid amide, or a polyimide resin, and (B) a solvent, and
that is used for preparing an organic insulating film for at least one of a first organic insulating film or a second organic insulating film in a method for producing a semiconductor device comprising the following processes (1) to (5):
Process (1) preparing a first semiconductor substrate comprising a first substrate body and the first organic insulating film and a first electrode provided on one side of the first substrate body;
Process (2) preparing a second semiconductor substrate comprising a second substrate body and the second organic insulating film and a plurality of second electrodes provided on one side of the second substrate body;
Process (3) breaking the second semiconductor substrate into pieces to obtain a plurality of semiconductor chips each having an organic insulating film portion corresponding to a portion of the second organic insulating film and at least one of the second electrodes;
Process (4) attaching the first organic insulating film of the first semiconductor substrate and the organic insulating film portion of the semiconductor chip to each other; and
Process (5) bonding the first electrode of the first semiconductor substrate and the second electrode of the semiconductor chip together.

2. A resin composition that comprises (A) at least one of a polyimide precursor, which is at least one resin selected from the group consisting of a polyamide acid, a polyamide acid ester, a polyamide acid salt, and a polyamide acid amide, or a polyimide resin and (B) a solvent, and
that is used for preparing a cured product to be polished by a chemical mechanical polishing method together with an electrode.

3. The resin composition according to claim 1, wherein (A) the polyimide precursor comprises a compound containing a structural unit represented by the following Formula (1): 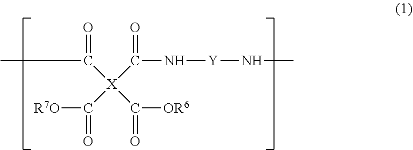
wherein in Formula (1), X represents a tetravalent organic group, Y represents a divalent organic group, and each of R⁶ and R⁷ independently represents a hydrogen atom or a monovalent organic group.

4. The resin composition according to claim 3, wherein the tetravalent organic group represented by X in Formula (1) is a group represented by the following Formula (E): 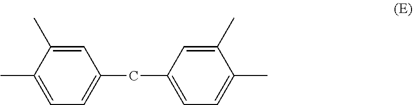
wherein in Formula (E), C represents a single bond, an alkylene group, an alkylene halide group, a carbonyl group, a sulfonyl group, an ether bond (—O—), a sulfide bond (—S—), a phenylene group, an ester bond (—O—C(═O)—), a silylene bond (—Si(R^{A})₂— in which each of the two R^{A}s independently represents a hydrogen atom, an alkyl group, or a phenyl group), a siloxane bond (—O—(Si(R^{B})₂—O—)ₙ in which each of the two R^{B}s independently represents a hydrogen atom, an alkyl group or a phenyl group, and n is an integer of 1 or 2 or more), or a divalent group combining at least two of these.

5. The resin composition according to claim 3, wherein the divalent organic group represented by Y in Formula (1) is a group represented by the following Formula (H): 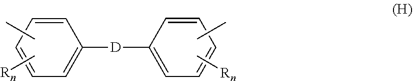
wherein in Formula (H), R independently represents an alkyl group, an alkoxy group, an alkyl halide group, a phenyl group, or a halogen atom; n independently represents an integer from 0 to 4, and D represents a single bond, an alkylene group, an alkylene halide group, a carbonyl group, a sulfonyl group, an ether bond (—O—), a sulfide bond (—S—), a phenylene group, an ester bond (—O—C(═O)—), a silylene bond (—Si(R^{A})₂— in which each of the two R^{A}s independently represents a hydrogen atom, an alkyl group, or a phenyl group), a siloxane bond (—O—(Si(R^{B})₂—O—)ₙ in which each of the two R^{B}s independently represents a hydrogen atom, an alkyl group or a phenyl group, and n is an integer of 1 or 2 or more), or a divalent group combining at least two of these.

6. The resin composition according to claim 3, wherein the monovalent organic group in each of R⁶ and R⁷ in Formula (1) is a group represented by the following Formula (2), an ethyl group, an isobutyl group, or a t-butyl group: 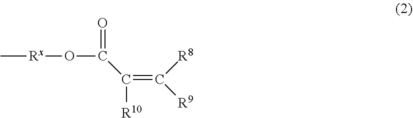
wherein in Formula (2), each of R⁸ to R¹⁰ independently represents a hydrogen atom or an aliphatic hydrocarbon group having from 1 to 3 carbon atoms, and R^{x} represents a divalent linking group.

7. The resin composition according to claim 1, wherein a content of (B) the solvent is from 1 to 10,000 parts by mass with respect to 100 parts by mass of a total of (A) the polyimide precursor and the polyimide resin.

8. The resin composition according to claim 1, wherein (B) the solvent contains at least one of the group consisting of compounds represented by the following Formula (3) to Formula (7): 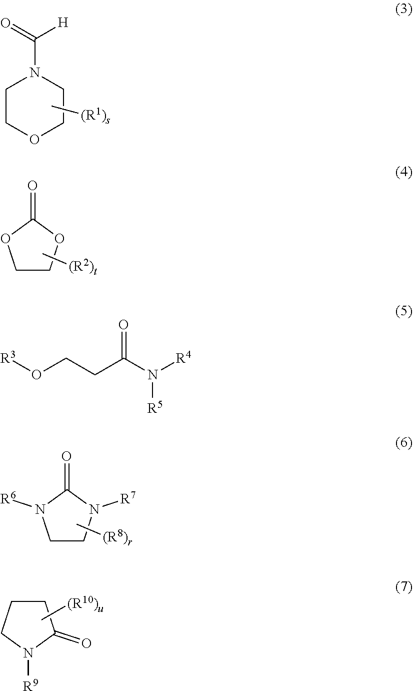
wherein in Formulas (3) to (7), each of R¹, R², R⁸, and R¹⁰ is independently an alkyl group having from 1 to 4 carbon atoms; each of R³ to R⁷ and R⁹ is independently a hydrogen atom or an alkyl group having from 1 to 4 carbon atoms; s is an integer from 0 to 8; t is an integer from 0 to 4; r is an integer from 0 to 4, and u is an integer from 0 to 3.

9. The resin composition according to claim 1, wherein a 5% thermal weight loss temperature of a cured product obtained by curing the resin composition is 200° C. or higher.

10. The resin composition according to claim 1, wherein a glass transition temperature of a cured product obtained by curing the resin composition is from 100° C. to 400° C.

11. The resin composition according to claim 1, wherein, for a cured product obtained by curing the resin composition, a ratio of a storage modulus G2 at a temperature 100° C. higher than a glass transition temperature (Tg) of the cured product as determined by dynamic viscoelasticity measurement to a storage modulus G1 at a temperature 100° C. lower than a glass transition temperature (Tg) of the cured product as determined by dynamic viscoelasticity measurement, G2/G1, is from 0.001 to 0.02.

12. The resin composition according to claim 1, further comprising (C) a photoinitiator and (D) a polymerizable monomer.

13. The resin composition of claim 1, which is a negative-type photosensitive resin composition or a positive-type photosensitive resin composition, for use in providing a plurality of through holes for arranging a plurality of terminal electrodes on an organic insulating film provided on one surface of a substrate body by a photolithographic process.

14. The resin composition according to claim 1, wherein a tensile modulus at 25° C. of a cured product is 7.0 GPa or less.

15. The resin composition of claim 1, wherein a thermal expansion coefficient of a cured product obtained by curing is 150 ppm/K or less.

16. A method for producing a semiconductor device, wherein the resin composition according to claim 1 is used for producing at least one organic insulating film of a first organic insulating film or a second organic insulating film, and wherein a semiconductor device is produced by performing the following processes (1) to (5):
Process (1) preparing a first substrate body and a first semiconductor substrate including the first organic insulating film or a first electrode provided on one side of the first substrate body;
Process (2) preparing a second substrate body and a second semiconductor substrate including the second organic insulating film and a plurality of second electrodes provided on one side of the second substrate body;
Process (3) breaking the second semiconductor substrate is broken into pieces to obtain a plurality of semiconductor chips each having an organic insulating film portion corresponding to a portion of the second organic insulating film and at least one of the second electrodes;
Process (4) attaching the first organic insulating film of the first semiconductor substrate and the organic insulating film portion of the semiconductor chip to each other; and
Process (5) bonding the first electrode of the first semiconductor substrate and the second electrode of the semiconductor chip together.

17. The method for producing a semiconductor device according to claim 16, wherein the first organic insulating film and the organic insulating film portion are bonded together at a temperature at which a temperature difference between the semiconductor chip and the first semiconductor substrate is within 10° C. in the process (4).

18-22. (canceled)

23. A semiconductor device comprising:
a first semiconductor substrate including a first substrate body, and a first organic insulating film and a first electrode provided on one side of the first substrate body; and
a semiconductor chip including a semiconductor chip substrate body, and an organic insulating film portion and a second electrode provided on one side of the semiconductor chip substrate body, wherein:
the first organic insulating film of the first semiconductor substrate and the organic insulating film portion of the semiconductor chip are bonded, and the first electrode of the first semiconductor substrate and the second electrode of the semiconductor chip are bonded, and
at least one of the first organic insulating film or the organic insulating film portion is an organic insulating film obtained by curing the resin composition according to claim 1.

24. A method for synthesizing a polyimide precursor, the method comprising:
a process of reacting tetracarboxylic dianhydride with a diamine compound represented by H₂N—Y—NH₂ (wherein Y is a divalent organic group) in 3-methoxy-N,N-dimethylpropanamide to obtain a polyamide acid solution; and
a process of allowing a dehydration condensation agent and a compound represented by R—OH (wherein R is a monovalent organic group) to act on the polyamide acid solution.

25. The method for synthesizing a polyimide precursor according to claim 24, wherein the dehydration condensation agent comprises at least one selected from the group consisting of trifluoroacetic anhydride, N,N′-dicyclohexylcarbodiimide (DCC), and 1,3-diisopropylcarbodiimide (DIC).
